(19) United States
(12) Patent Application Publication
(10) Pub. No.: US 2026/0206157 A1
(43) Pub. Date: Jul. 16, 2026

(54) ELECTRONIC MODULES AND ASSOCIATED SYSTEMS

(71) Applicant: SeeScan, Inc., San Diego, CA (US)

(72) Inventors: Mark S. Olsson, La Jolla, CA (US); David C. Parsons, San Marcos, CA (US); David B. Sullivan, Escondido, CA (US); Alexander L. Warren, Escondido, CA (US); Ryan B. Levin, San Diego, CA (US)

(21) Appl. No.: 19/324,044

(22) Filed: Sep. 9, 2025

Related U.S. Application Data
(60) Provisional application No. 63/692,642, filed on Sep. 9, 2024.

(51) Int. Cl. H05K 5/02; H05K 5/00; H05K 7/14; H05K 7/20

(52) U.S. Cl. CPC H05K 5/0247; H05K 5/0052; H05K 5/0217; H05K 7/1427; H05K 7/20409

(57) ABSTRACT

Electronic circuit modules including a housing, electronic circuit board disposed in the housing, and a high density electrical connector to couple an electrical cable between the electronic circuit board and another circuit board or electrical connection point are disclosed. Some embodiments may include a heat sink, spring plate, and antenna coupled via coaxial cable through the heat sink to the electronic circuit board.

### FIELD

This disclosure relates generally to electronic modules and associated apparatus and systems wherein such modules are used. More specifically, but not exclusively, the disclosure is directed to modules for use in electronic utility locating apparatus and systems, camera apparatus and systems, camera control unit (CCU) apparatus and systems, and peripherals for use with these systems.

### BRIEF DESCRIPTION OF THE DRAWINGS

The present application may be more fully appreciated in connection with the following detailed description taken in conjunction with the accompanying drawings, wherein:

FIG. 1 is an illustration of one embodiment of an electronics module in accordance with aspects of the disclosure;

FIG. 2 is an exploded view of the electronics module embodiment of FIG. 1;

FIG. 3 is an illustration of example injection molded electronics module housing embodiments in accordance with aspects of the disclosure;

FIG. 4 is an illustration of another example of injection molded electronics module housing embodiments in accordance with aspects of the disclosure;

FIG. 5A is an illustration of an embodiment of an injection molded housing in accordance with aspects of the disclosure, as shown in an isometric view in accordance with aspects of the disclosure;

FIG. 5B is an illustration of the embodiment of FIG. 5A as seen from a side view;

FIG. 6A is an illustration of another embodiment of an electronics module printed circuit board (PCB) in accordance with aspects of the disclosure, as seen on a connector side or bottom side;

FIG. 6B is an illustration of the embodiment of FIG. 6A as seen on an integrated circuit and wireless output connector side or top side;

FIG. 7A is an illustration of another embodiment of an electronics module showing a housing embodiment and a PCB embodiment in accordance with aspects of the disclosure, positioned in the housing embodiment as seen from a bottom or lower side;

FIG. 7B is an illustration of the electronics module embodiment of FIG. 7A as shown from a top or upper side.

FIG. 8A is an illustration of another electronics module embodiment in accordance with aspects of the disclosure, showing a housing embodiment and a PCB embodiment as seen from a bottom or lower side;

FIG. 8B is an illustration of the lower or bottom side of the PCB embodiment of FIG. 8A removed from the housing embodiment;

FIG. 9A is an illustration of an embodiment of a locator circuit board assembly in accordance with aspects of the disclosure, including two module embodiments in accordance with aspects of the disclosure as seen from one side of a locator circuit board embodiment;

FIG. 9B is an illustration of the locator circuit board embodiment of FIG. 9A as seen from the other side of the locator circuit board embodiment;

FIG. 10A is an illustration of another electronics module embodiment in accordance with aspects of the disclosure as seen from the top or upper side, including a housing embodiment having cooling fins or features;

FIG. 10B is an illustration of the embodiment of FIG. 10A, as seen from the bottom or lower side;

FIG. 11 is an illustration of a cutaway view from the side of an electronics module embodiment such as shown in FIG. 10A in accordance with aspects of the disclosure, showing internal elements and module configuration;

FIG. 12A is an illustration of another electronics module embodiment in accordance with aspects of the disclosure as seen in isometric view from the top or upper side, including a housing embodiment and separate heat sink including cooling fins or features;

FIG. 12B is an illustration of the electronics module embodiment of FIG. 12A as seen from the top or upper side;

FIG. 12C is an illustration of the electronics module embodiment of FIG. 12A as seen from the bottom or lower side;

FIG. 12D is an illustration of the electronics module embodiment of FIG. 12A as seen from a side view;

FIG. 12E is an illustration of the electronics module embodiment of FIG. 12A in disassembled view showing various elements of the electronics module embodiment;

FIG. 12F is an illustration of the heat sink embodiment of the electronics module of FIG. 12A as seen from a bottom or lower side;

FIG. 12G is an illustration of the spring loading element of the electronics module of FIG. 12A as seen from a side view;

FIG. 12H is an illustration of the spring loading element of the electronics module of FIG. 12A as seen in an isometric view from the top or upper side;

FIG. 12I is an illustration of the heat sink and spring loading element of the electronics module of FIG. 12A as positioned within the module to control tensioning of the heat sink to the PCB;

FIG. 13 is an illustration of a cutaway view from the side of an electronics module embodiment such as shown in FIG. 12A in accordance with aspects of the disclosure, showing internal elements and module configuration;

FIG. 14 is an illustration of an electronics module embodiment adjacent to a PCB board on which the module may be disposed in accordance with aspects of the disclosure;

FIG. 15 illustrated details of another electronic module embodiment in exploded view, in accordance with aspects of the present disclosure;

FIGS. 16A & 16B illustrate details of the electronics module of FIG. 15 in an assembled configuration, in accordance with aspects of the present disclosure;

FIGS. 17A & 17B illustrate additional details of the printed circuit board (PCB) as shown in FIGS. 15 and 16A & B in accordance with aspects of the present disclosure;

FIGS. 18A & 18B illustrate details of a housing or case embodiment of an electronics module in accordance with aspects of the present disclosure; and

FIG. 19 illustrated details of a heat sink element embodiment of an electronics module in accordance with aspects of the present disclosure; and

FIG. 20 illustrates details of a spring element embodiment of an electronics module in the form of a spring plate in accordance with aspects of the present disclosure.

### DETAILED DESCRIPTION OF EMBODIMENTS

### Overview

This disclosure relates to electronic circuit modules (also denoted herein as “modules” for brevity) that may be used in a variety of electronic apparatus, assemblies, and systems.

For example, in some applications, module embodiments such as described herein may be used in utility locator devices, associated accessories and apparatus such as but not limited to utility locating transmitter and induction devices, inspection camera apparatus and systems, camera control units, induction devices, as well as other utility locating and inspection camera system components and devices.

In other exemplary applications, module embodiments may be used in oceanographic apparatus, devices, and systems such as underwater power supplies, lighting devices and systems, camera devices and systems, and other associated components and devices.

Additional details of example apparatus, device, and system embodiments where modules in accordance with aspects of the disclosures herein may be used in further embodiments include, but are not limited to, those disclosed in co-assigned patents and patent applications including: U.S. Pat. No. 6,545,704, issued Jul. 7, 1999, entitled VIDEO PIPE INSPECTION DISTANCE MEASURING SYSTEM; U.S. Pat. No. 6,958,767, issued Oct. 25, 2005, entitled VIDEO PIPE INSPECTION SYSTEM EMPLOYING NON-ROTATING CABLE STORAGE DRUM; U.S. Pat. No. 7,009,399, issued Mar. 7, 2006, entitled OMNIDIRECTIONAL SONDE AND LINE LOCATOR; U.S. Pat. No. 7,136,765, issued Nov. 14, 2006, entitled A BURIED OBJECT LOCATING AND TRACING METHOD AND SYSTEM EMPLOYING PRINCIPAL COMPONENTS ANALYSIS FOR BLIND SIGNAL DETECTION; U.S. Pat. No. 7,221,136, issued May 22, 2007, entitled SONDES FOR LOCATING UNDERGROUND PIPES AND CONDUITS; U.S. Pat. No. 7,276,910, issued Oct. 2, 2007, entitled A COMPACT SELF-TUNED ELECTRICAL RESONATOR FOR BURIED OBJECT LOCATOR APPLICATIONS; U.S. Pat. No. 7,288,929, issued Oct. 30, 2007, entitled INDUCTIVE CLAMP FOR APPLYING SIGNAL TO BURIED UTILITIES; U.S. Pat. No. 7,336,078, issued Feb. 26, 2008, entitled MULTI-SENSOR MAPPING OMNIDIRECTIONAL SONDE AND LINE LOCATOR; U.S. Pat. No. 7,498,797, issued Mar. 3, 2009, entitled LOCATOR WITH CURRENT-MEASURING CAPABILITY; U.S. Pat. No. 7,498,816, issued Mar. 3, 2009, entitled OMNIDIRECTIONAL SONDE AND LINE LOCATOR; U.S. Pat. No. 7,518,374, issued Apr. 14, 2009, entitled RECONFIGURABLE PORTABLE LOCATOR EMPLOYING MULTIPLE SENSOR ARRAYS HAVING FLEXIBLE NESTED ORTHOGONAL ANTENNAS; U.S. Pat. No. 7,557,559, issued Jul. 7, 2009, entitled COMPACT LINE ILLUMINATOR FOR BURIED PIPES AND CABLES; U.S. Pat. No. 7,619,516, issued Nov. 17, 2009, entitled SINGLE AND MULTI-TRACE OMNIDIRECTIONAL SONDE AND LINE LOCATORS AND TRANSMITTER USED THEREWITH; U.S. Pat. No. 7,619,516, issued Nov. 17, 2009, entitled SINGLE AND MULTI-TRACE OMNIDIRECTIONAL SONDE AND LINE LOCATORS AND TRANSMITTER USED THEREWITH; U.S. Pat. No. 7,733,077, issued Jun. 8, 2010, entitled MULTI-SENSOR MAPPING OMNIDIRECTIONAL SONDE AND LINE LOCATORS AND TRANSMITTER USED THEREWITH; U.S. Pat. No. 7,741,848, issued Jun. 22, 2010, entitled ADAPTIVE MULTICHANNEL LOCATOR SYSTEM FOR MULTIPLE PROXIMITY DETECTION; U.S. Pat. No. 7,755,360, issued Jul. 13, 2010, entitled PORTABLE LOCATOR SYSTEM WITH JAMMING REDUCTION; U.S. Pat. No. 7,830,149, issued Nov. 9, 2010, entitled AN UNDERGROUND UTILITY LOCATOR WITH A TRANSMITTER, A PAIR OF UPWARDLY OPENING POCKET AND HELICAL COIL TYPE ELECTRICAL CORDS; U.S. Pat. No. 7,864,980, issued Jan. 4, 2011, entitled SONDES FOR LOCATING UNDERGROUND PIPES AND CONDUITS; U.S. Pat. No. 7,948,236, issued May 24, 2011, entitled ADAPTIVE MULTICHANNEL LOCATOR SYSTEM FOR MULTIPLE PROXIMITY DETECTION; U.S. Pat. No. 7,969,151, issued Jun. 28, 2011, entitled PRE-AMPLIFIER AND MIXER CIRCUITRY FOR A LOCATOR ANTENNA; U.S. Pat. No. 7,990,151, issued Aug. 2, 2011, entitled TRI-POD BURIED LOCATOR SYSTEM; U.S. Pat. No. 8,013,610, issued Sep. 6, 2011, entitled HIGH Q SELF-TUNING LOCATING TRANSMITTER; U.S. Pat. No. 8,035,390, issued Oct. 11, 2011, entitled OMNIDIRECTIONAL SONDE AND LINE LOCATOR; U.S. Pat. No. 8,106,660, issued Jan. 31, 2012, entitled SONDE ARRAY FOR USE WITH BURIED LINE LOCATOR; U.S. Pat. No. 8,203,343, issued Jun. 19, 2012, entitled RECONFIGURABLE PORTABLE LOCATOR EMPLOYING MULTIPLE SENSOR ARRAYS HAVING FLEXIBLE NESTED ORTHOGONAL ANTENNAS; U.S. Pat. No. 8,248,056, issued Aug. 21, 2012, entitled A BURIED OBJECT LOCATOR SYSTEM EMPLOYING AUTOMATED VIRTUAL DEPTH EVENT DETECTION AND SIGNALING; U.S. Pat. No. 8,264,226, issued Sep. 11, 2012, entitled SYSTEM AND METHOD FOR LOCATING BURIED PIPES AND CABLES WITH A MAN PORTABLE LOCATOR AND A TRANSMITTER IN A MESH NETWORK; U.S. patent application Ser. No. 13/769,202, filed Feb. 15, 2013, entitled SMART PAINT STICK DEVICES AND METHODS; U.S. patent application Ser. No. 13/793,168, filed Mar. 11, 2013, entitled BURIED OBJECT LOCATORS WITH CONDUCTIVE ANTENNA BOBBINS; U.S. Pat. No. 8,395,661, issued Mar. 12, 2013, entitled PIPE INSPECTION SYSTEM WITH SELECTIVE IMAGE CAPTURE; U.S. patent application Ser. No. 14/027,027, filed Sep. 13, 2013, entitled SONDE DEVICES INCLUDING A SECTIONAL FERRITE CORE STRUCTURE; U.S. patent application Ser. No. 14/033,349, filed Sep. 20, 2013, entitled AN UNDERGROUND UTILITY LOCATOR WITH A TRANSMITTER, A PAIR OF UPWARDLY OPENING POCKET AND HELICAL COIL TYPE ELECTRICAL CORDS; U.S. Pat. No. 8,547,428, issued Oct. 1, 2013, entitled PIPE MAPPING SYSTEM; U.S. Pat. No. 8,564,295, issued Oct. 22, 2013, entitled METHOD FOR SIMULTANEOUSLY DETERMINING A PLURALITY OF DIFFERENT LOCATIONS OF THE BURIED OBJECTS AND SIMULTANEOUSLY INDICATING THE DIFFERENT LOCATIONS TO A USER; U.S. patent application Ser. No. 14/148,649, filed Jan. 6, 2014, entitled MAPPING LOCATING SYSTEMS & METHODS; U.S. Pat. No. 8,773,133, issued Jul. 8, 2014, entitled ADAPTIVE MULTICHANNEL LOCATOR SYSTEM FOR MULTIPLE PROXIMITY DETECTION; U.S. Pat. No. 8,841,912, issued Sep. 23, 2014, entitled PRE-AMPLIFIER AND MIXER CIRCUITRY FOR A LOCATOR ANTENNA; U.S. Pat. No. 9,041,794, issued May 26, 2015, entitled PIPE MAPPING SYSTEMS AND METHODS; U.S. Pat. No. 9,057,754, issued Jun. 16, 2015, entitled ECONOMICAL MAGNETIC LOCATOR APPARATUS AND METHOD; U.S. Pat. No. 9,081,109, issued Jul. 14, 2015, entitled GROUND-TRACKING DEVICES FOR USE WITH A MAPPING LOCATOR; U.S. Pat. No. 9,080,992, issued Jul. 14, 2015, entitled ADJUSTABLE VARIABLE RESOLUTION INSPECTION SYSTEMS AND METHODS; U.S. Pat. No. 9,085,007, issued Jul. 21, 2015, entitled MARKING PAINT APPLICATOR FOR PORTABLE LOCATOR; U.S. Pat. No. 9,207,350, issued Dec. 8, 2015, entitled BURIED OBJECT LOCATOR APPARATUS WITH SAFETY LIGHTING ARRAY; U.S. Pat. No. 9,222,809, issued Dec. 29, 2015, entitled PORTABLE PIPE INSPECTION SYSTEMS AND APPARATUS; U.S. Pat. No. 9,341,740, issued May 17, 2016, entitled OPTICAL GROUND TRACKING APPARATUS, SYSTEMS, AND METHODS; U.S. Pat. No. 9,372,117, issued Jun. 21, 2016, entitled OPTICAL GROUND TRACKING APPARATUS, SYSTEMS, AND METHODS; U.S. patent application Ser. No. 15/187,785, filed Jun. 21, 2016, entitled BURIED UTILITY LOCATOR GROUND TRACKING APPATUS, SYSTEMS, AND METHODS; U.S. Pat. No. 9,411,066, issued Aug. 9, 2016, entitled SONDES & METHODS FOR USE WITH BURIED LINE LOCATOR SYSTEMS; U.S. Pat. No. 9,411,067, issued Aug. 9, 2016, entitled GROUND-TRACKING SYSTEMS AND APPARATUS; U.S. Pat. No. 9,435,907, issued Sep. 6, 2016, entitled PHASE SYNCHRONIZED BURIED OBJECT LOCATOR APPARATUS, SYSTEMS, AND METHODS; U.S. Pat. No. 9,465,129, issued Oct. 11, 2016, entitled IMAGE-BASED MAPPING LOCATING SYSTEM; U.S. Pat. No. 9,468,954, issued October 18, 2016, entitled PIPE INSPECTION SYSTEM WITH JETTER PUSH-CABLE; U.S. Pat. No. 9,494,706, issued Nov. 15, 2016, entitled OMNI-INDUCER TRANSMITTING DEVICES AND METHODS; U.S. patent application Ser. No. 15/846,102, filed December 16, 2016, entitled SYSTEMS AND METHODS FOR ELECTRONICALLY MARKING, LOCATING AND VIRTUALLY DISPLAYING BURIED UTILITIES; U.S. patent application Ser. No. 15/866,360, filed Jan. 9, 2017, entitled TRACKABLE DISTANCE MEASURING DEVICES, SYSTEMS, AND METHODS; U.S. Pat. No. 9,927,368, issued Mar. 27, 2021, entitled SELF-LEVELING INSPECTION SYSTEMS AND METHODS; U.S. Pat. No. 9,571,326, issued Feb. 14, 2017, entitled METHOD AND APPARATUS FOR HIGH-SPEED DATA TRANSFER EMPLOYING SELF-SYNCHRONIZING QUADRATURE AMPLITUDE MODULATION (QAM); U.S. Pat. No. 9,599,740, issued Mar. 21, 2017, entitled USER INTERFACES FOR UTILITY LOCATORS; United States patent Application, filed Apr. 25, 2017, entitled SYSTEMS AND METHODS FOR LOCATING AND/OR MAPPING BURIED UTILITIES USING VEHICLE-MOUNTED LOCATING DEVICES; United States patent Application, filed May 9, 2017, entitled BORING INSPECTION SYSTEMS AND METHODS; U.S. Pat. No. 9,651,711, issued May 16, 2017, entitled HORIZONTAL BORING INSPECTION DEVICE AND METHODS; U.S. Pat. No. 9,684,090, issued Jun. 20, 2017, entitled NULLED-SIGNAL LOCATING DEVICES, SYSTEMS, AND METHODS; U.S. Pat. No. 9,696,447, issued Jul. 4, 2017, entitled BURIED OBJECT LOCATING METHODS AND APPARATUS USING MULTIPLE ELECTROMAGNETIC SIGNALS; U.S. Pat. No. 9,696,448, issued Jul. 4, 2017, entitled GROUND-TRACKING DEVICES AND METHODS FOR USE WITH A UTILITY LOCATOR; U.S. Pat. No. 9,703,002, issued Jun. 11, 2017, entitled UTILITY LOCATOR SYSTEMS & METHODS; U.S. patent application Ser. No. 15/670,845, filed Aug. 7, 2016, entitled HIGH FREQUENCY AC-POWERED DRAIN CLEANING AND INSPECTION APPARATUS & METHODS; U.S. Patent Application Ser. No. 15/681,250, filed Aug. 18, 2017, entitled ELECTRONIC MARKER DEVICES AND SYSTEMS; U.S. patent application Ser. No. 15/681,409, filed Aug. 20, 2017, entitled WIRELESS BURIED PIPE & CABLE LOCATING SYSTEMS; U.S. Pat. No. 9,746,572, issued Aug. 29, 2017, entitled ELECTRONIC MARKER DEVICES AND SYSTEMS; U.S. Pat. No. 9,746,573, issued Aug. 29, 2017, entitled WIRELESS BURIED PIPE AND CABLE LOCATING SYSTEMS; U.S. Pat. No. 9,769,366, issued Sep. 29, 2017, entitled SELF-GROUNDING TRANSMITTER PORTABLE CAMERA CONTROLLER FOR USE WITH PIPE INSPECTION SYSTEMS; U.S. Pat. No. 9,784,837, issued Oct. 10, 2017, entitled OPTICAL GROUND TRACKING APPARATUS, SYSTEMS & METHODS; U.S. Pat. No. 9,798,033, issued Oct. 24, 2017, entitled SONDE DEVICES INCLUDING A SECTIONAL FERRITE CORE; U.S. patent application Ser. No. 15/811,361, filed Nov. 13, 2017, entitled OPTICAL GROUND-TRACKING APPARATUS, SYSTEMS, AND METHODS; U.S. Pat. No. 9,835,564, issued Dec. 5, 2017, entitled MULTI-CAMERA PIPE INSPECTION APPARATUS, SYSTEMS, AND METHODS; U.S. Pat. No. 9,841,503, issued Dec. 12, 2017, entitled OPTICAL GROUND-TRACKING APPARATUS, SYSTEMS, AND METHODS; U.S. patent application Ser. No. 15/846,102, filed Dec. 18, 2017, entitled SYSTEMS AND METHOD FOR ELECTRONICALLY MARKING, LOCATING AND VIRTUALLY DISPLAYING BURIED UTILITIES; U.S. patent application Ser. No. 15/866,360, filed Jan. 9, 2018, entitled TRACKED DISTANCE MEASURING DEVICES, SYSTEMS, AND METHODS; U.S. Patent Application Ser. No. 16/255,524, filed Jan. 23, 2018, entitled RECHARGEABLE BATTERY PACK ONBOARD CHARGE STATE INDICATION METHODS AND APPARATUS; U.S. Pat. No. 9,891,337, issued Feb. 13, 2018, entitled UTILITY LOCATOR TRANSMITTER DEVICES, SYSTEMS, and METHODS WITH DOCKABLE APPARATUS; U.S. Pat. No. 9,914,157, issued Mar. 13, 2018, entitled METHODS AND APPARATUS FOR CLEARING OBSTRUCTIONS WITH A JETTER PUSH-CABLE APPARATUS; U.S. patent application Ser. No. 15/925,643, issued Mar. 19, 2018, entitled PHASE-SYNCHRONIZED BURIED OBJECT TRANSMITTER AND LOCATOR METHODS AND APPARATUS; U.S. patent application Ser. No. 15/925,671, issued Mar. 19, 2018, entitled MULTI-FREQUENCY LOCATING SYSTEMS AND METHODS; U.S. patent application Ser. No. 15/936,250, filed Mar. 26, 2018, entitled GROUND TRACKING APPARATUS, SYSTEMS, AND METHODS; U.S. Pat. No. 9,927,545, issued Mar. 27, 2018, entitled MULTI-FREQUENCY LOCATING SYSTEMS & METHODS; U.S. Pat. No. 9,928,613, issued Mar. 27, 2018, entitled GROUND TRACKING APPARATUS, SYSTEMS, AND METHODS; U.S. patent application Ser. No. 15/250,666, filed Mar. 27, 2018, entitled PHASE-SYNCHRONIZED BURIED OBJECT TRANSMITTER AND LOCATOR METHODS AND APPARATUS; U.S. Pat. No. 9,880,309, issued Mar. 28, 2018, entitled UTILITY LOCATOR TRANSMITTER APPARATUS & METHODS; U.S. patent application Ser. No. 15/954,486, filed Apr. 16, 2018, entitled UTILITY LOCATOR APPARATUS, SYSTEMS, AND METHODS; U.S. Pat. No. 9,945,976, issued Apr. 17, 2018, entitled UTILITY LOCATOR APPARATUS, SYSTEMS, AND METHODS; U.S. Pat. No. 9,989,662, issued Jun. 5, 2018, entitled BURIED OBJECT LOCATING DEVICE WITH A PLURALITY OF SPHERICAL SENSOR BALLS THAT INCLUDE A PLURALITY OF ORTHOGONAL ANTENNAE; U.S. Pat. No. 10,001,425, issued Jun. 19, 2018, entitled PORTABLE CAMERA CONTROLLER PLATFORM FOR USE WITH PIPE INSPECTION SYSTEM; U.S. Pat. No. 10,009,582, issued Jun. 26, 2018, entitled PIPE INSPECTION SYSTEM WITH REPLACEABLE CABLE STORAGE DRUM; U.S. patent application Ser. No. 16/036,713, issued Jul. 16, 2018, entitled UTILITY LOCATOR APPARATUS AND SYSTEMS; U.S. Pat. No. 10,027,526, issued Jul. 17, 2018, entitled METHOD AND APPARATUS FOR HIGH-SPEED DATA TRANSFER EMPLOYING SELF-SYNCHRONIZING QUADRATURE AMPLITUDE MODULATION; U.S. Pat. No. 10,024,994, issued Jul. 17, 2018, entitled WEARABLE MAGNETIC FIELD UTILITY LOCATOR SYSTEM WITH SOUND FIELD GENERATION; U.S. Pat. No. 10,042,072, issued Aug. 7, 2018, entitled OMNI-INDUCER TRANSMITTING DEVICES AND METHODS; U.S. Pat. No. 10,059,504, issued Aug. 28, 2018, entitled MARKING PAINT APPLICATOR FOR USE WITH PORTABLE UTILITY LOCATOR; U.S. patent application Ser. No. 16/049,699, filed Jul. 30, 2018, entitled OMNI-INDUCER TRANSMITTING DEVICES AND METHODS; U.S. patent application Ser. No. 16/121,379, filed Sep. 4, 2018, entitled KEYED CURRENT SIGNAL UTILITY LOCATING SYSTEMS AND METHODS; U.S. patent application Ser. No. 16/125,768, filed Sep. 10, 2018, entitled BURIED OBJECT LOCATOR APPARATUS AND METHODS; U.S. patent application Ser. No. 16/133,642, issued Sep. 17, 2018, entitled MAGNETIC UTILITY LOCATOR DEVICES AND METHODS; U.S. Pat. No. 10,078,149, issued Sep. 18, 2018, entitled BURIED OBJECT LOCATORS WITH DODECAHEDRAL ANTENNA NODES; U.S. Pat. No. 10,082,591, issued Sep. 25, 2018, entitled MAGNETIC UTILITY LOCATOR DEVICES & METHODS; U.S. Pat. No. 10,082,599, issued Sep. 25, 2018, entitled MAGNETIC SENSING BURIED OBJECT LOCATOR INCLUDING A CAMERA; U.S. Pat. No. 10,090,498, issued Oct. 2, 2018, entitled MODULAR BATTERY PACK APPARATUS, SYSTEMS, AND METHODS INCLUDING VIRAL DATA AND/OR CODE TRANSFER; U.S. patent application Ser. No. 16/160,874, filed Oct. 15, 2018, entitled TRACKABLE DIPOLE DEVICES, METHODS, AND SYSTEMS FOR USE WITH MARKING PAINT STICKS; U.S. Pat. No. 10,100,507, issued October 16, 2018, entitled PIPE CLEARING CABLES AND APPARATUS; U.S. Pat. No. 10,105,723, issued Oct. 23, 2018, entitled TRACKABLE DIPOLE DEVICES, METHODS, AND SYSTEMS FOR USE WITH MARKING PAINT STICKS; U.S. patent application Ser. No. 16/222,994, filed Dec. 17, 2018, entitled UTILITY LOCATORS WITH RETRACTABLE SUPPORT STRUCTURES AND APPLICATIONS THEREOF; U.S. Pat. No. 10,105,723, issued Oct. 23, 2018, entitled TRACKABLE DIPOLE DEVICES, METHODS, AND SYSTEMS FOR USE WITH MARKING PAINT STICKS; U.S. Pat. No. 10,162,074, issued Dec. 25, 2018, entitled UTILITY LOCATORS WITH RETRACTABLE SUPPORT STRUCTURES AND APPLICATIONS THEREOF; U.S. patent application Ser. No. 16/241,864, filed Jan. 7, 2019, entitled TRACKED DISTANCE MEASURING DEVICES, SYSTEMS, AND METHODS; U.S. Pat. No. 10,247,845, issued Apr. 2, 2019, entitled UTILITY LOCATOR TRANSMITTER APPARATUS AND METHODS; U.S. Pat. No. 10,274,632, issued Apr. 20, 2019, entitled UTILITY LOCATING SYSTEMS WITH MOBILE BASE STATION; U.S. Pat. No. 10,288,997, issued May 14, 2019, entitled ROTATING CONTACT ASSEMBLIES FOR SELF-LEVELING CAMERA HEADS; U.S. patent application Ser. No. 29/692,937, filed May 29, 2019, entitled BURIED OBJECT LOCATOR; U.S. patent application Ser. No. 16/436,903, filed Jun. 10, 2019, entitled OPTICAL GROUND TRACKING APPARATUS, SYSTEMS, AND METHODS FOR USE WITH BURIED UTILITY LOCATORS; U.S. Pat. No. 10,317,559, issued Jun. 11, 2019, entitled GROUND-TRACKING DEVICES AND METHODS FOR USE WITH A UTILITY LOCATOR; U.S. patent application Ser. No. 16/449,187, filed Jun. 21, 2019, entitled ELECTROMAGNETIC MARKER DEVICES FOR BURIED OR HIDDEN USE; U.S. Pat. No. 10,353,103, issued Jul. 16, 2019, entitled SELF-STANDING MULTI-LEG ATTACHMENT DEVICES FOR USE WITH UTILITY LOCATORS; U.S. Pat. No. 10,371,305, issued Aug. 6, 2019, entitled DOCKABLE TRIPODAL CAMERA CONTROL UNIT; U.S. patent application Ser. No. 16/551,653, filed Aug. 26, 2019, entitled BURIED UTILITY MARKER DEVICES, SYSTEMS, AND METHODS; U.S. Pat. No. 10,324,188, issued Oct. 9, 2019, entitled OPTICAL GROUND TRACKING APPARATUS, SYSTEMS, AND METHODS FOR USE WITH BURIED UTILITY LOCATORS; U.S. patent application Ser. No. 16/559,576, filed Sep. 3, 2019, entitled VIDEO PIPE INSPECTION SYSTEMS WITH VIDEO INTEGRATED WITH ADDITIONAL SENSOR DATA; U.S. patent application Ser. No. 16/588,834, filed Sep. 30, 2019, entitled VIDEO INSPECTION SYSTEM WITH WIRELESS ENABLED CABLE STORAGE DRUM; U.S. Pat. No. 10,440,332, issued Oct. 8, 2019, entitled INSPECTION CAMERA DEVICES AND METHODS WITH SELECTIVELY ILLUMINATED MULTISENSOR IMAGING; U.S. Pat. No. 10,534,105, issued Jan. 14, 2020, entitled UTILITY LOCATING TRANSMITTER APPARATUS AND METHODS; U.S. patent application Ser. No. 16/773,952, filed Jan. 27, 2020, entitled MAGNETIC FIELD CANCELING AUDIO DEVICES; U.S. patent application Ser. No. 16/780,813, filed Feb. 3, 2020, entitled RESILIENTLY DEFORMABLE MAGNETIC FIELD CORE APPARATUS AND APPLICATIONS; U.S. Pat. No. 10,555,086, issued Feb. 4, 2020, entitled MAGNETIC FIELD CANCELING AUDIO SPEAKERS FOR USE WITH BURIED UTILITY LOCATORS OR OTHER DEVICES; U.S. patent application Ser. No. 16/786,935, filed Feb. 10, 2020, entitled SYSTEMS AND METHODS FOR UNIQUELY IDENTIFYING BURIED UTILITIES IN A MULTI-UTILITY ENVIRONMENT; U.S. patent application Ser. No. 16/792,047, filed Feb. 14, 2020, entitled SATELLITE AND MAGNETIC FIELD SONDE APPARATUS AND METHODS; U.S. Pat. No. 10,571,594, issued Feb. 25, 2020, entitled UTILITY LOCATOR DEVICES, SYSTEMS, AND METHODS WITH SATELLITE AND MAGNETIC FIELD SONDE ANTENNA SYSTEMS; U.S. patent application Ser. No. 16/833,426, filed Mar. 27, 2020, entitled LOW COST, HIGH PERFORMANCE SIGNAL PROCESSING IN A MAGNETIC-FIELD SENSING BURIED UTILITY LOCATOR SYSTEM; U.S. patent application Ser. No. 17/235,507, filed Apr. 20, 2021, entitled UTILITY LOCATING DEVICES EMPLOYING MULTIPLE SPACED APART GNSS ANTENNAS; U.S. patent application Ser. No. 16/872,362, filed May 11, 2020, entitled BURIED LOCATOR SYSTEMS AND METHODS; United States Patent Application Ser. No. 16/882,719, filed May 25, 2020, entitled UTILITY LOCATING SYSTEMS, DEVICES, AND METHODS USING RADIO BROADCAST SIGNALS; U.S. Pat. No. 10,677,820, issued Jun. 9, 2020, entitled BURIED LOCATOR SYSTEMS AND METHODS; U.S. patent application Ser. No. 16/902,245, filed Jun. 15, 2020, entitled LOCATING DEVICES, SYSTEMS, AND METHODS USING FREQUENCY SUITES FOR UTILITY DETECTION; U.S. patent application Ser. No. 16/908,625, filed Jun. 22, 2020, entitled ELECTROMAGNETIC MARKER DEVICES WITH SEPARATE RECEIVE AND TRANSMIT ANTENNA ELEMENTS; U.S. Pat. No. 10,690,795, issued Jun. 23, 2020, entitled LOCATING DEVICES, SYSTEMS, AND METHODS USING FREQUENCY SUITES FOR UTILITY DETECTION; U.S. patent application Ser. No. 16/921,775, filed Jul. 6, 2020, entitled AUTO-TUNING CIRCUIT APPARATUS AND METHODS; U.S. Provisional Patent Application 63/055,278, filed Jul. 22, 2020, entitled VEHICLE-BASED UTILITY LOCATING USING PRINCIPAL COMPONENTS; U.S. patent application Ser. No. 16/995,801, filed Aug. 17, 2020, entitled UTILITY LOCATOR TRANSMITTER DEVICES, SYSTEMS, AND METHODS; U.S. patent application Ser. No. 17/001,200, filed Aug. 24, 2020, entitled MAGNETIC SENSING BURIED UTLITITY LOCATOR INCLUDING A CAMERA; U.S. patent Ser. No. 16/995,793, filed Aug. 17, 2020, entitled UTILITY LOCATOR APPARATUS AND METHODS; U.S. Pat. No. 10,754,053, issued Aug. 25, 2020, entitled UTILITY LOCATOR TRANSMITTER DEVICES, SYSTEMS, AND METHODS WITH DOCKABLE APPARATUS; U.S. Pat. No. 10,761,233, issued Sep. 1, 2020, entitled SONDES AND METHODS FOR USE WITH BURIED LINE LOCATOR SYSTEMS; U.S. Pat. No. 10,761,239, issued Sep. 1, 2020, entitled MAGNETIC SENSING BURIED UTILITY LOCATOR INCLUDING A CAMERA; U.S. patent application Ser. No. 17/013,831, filed Sep. 7, 2020, entitled MULTIFUNCTION BURIED UTILITY LOCATING CLIPS; U.S. patent application Ser. No. 17/014,646, filed Sep. 8, 2020, entitled INTEGRATED FLEX-SHAFT CAMERA SYSTEM AND HAND CONTROL; U.S. patent application Ser. No. 17/068,156, filed Oct. 12, 2020, entitled DUAL SENSED LOCATING SYSTEMS AND METHODS; U.S. Pat. No. 10,845,497, issued Nov. 24, 2020, entitled PHASE-SYNCHRONIZED BURIED OBJECT TRANSMITTER AND LOCATOR METHODS AND APPARATUS; U.S. patent application Ser. No. 17/110,273, filed Dec. 2, 2020, entitled INTEGRAL DUAL CLEANER CAMERA DRUM SYSTEMS AND METHODS; U.S. Pat. No. 10,859,727, issued Dec. 8, 2020, entitled ELECTRONIC MARKER DEVICES AND SYSTEMS; U.S. Pat. No. 10,935,686, issued Mar. 2, 2021, entitled UTILITY LOCATING SYSTEM WITH MOBILE BASE STATION; U.S. patent application Ser. No. 17/190,400, filed Mar. 3, 2021, entitled DOCKABLE CAMERA REEL AND CCU SYSTEM; U.S. Pat. No. 9,927,368, issued Mar. 27, 2021, entitled SELF-LEVELING INSPECTION SYSTEMS AND METHODS; U.S. Pat. No. 10,976,462, issued Apr. 13, 2021, entitled VIDEO INPECTION SYSTEMS WITH PERSONAL COMMUNICATION DEVICE USER INTERFACES; U.S. patent application Ser. No. 17/501,670, filed Oct. 14, 2021, entitled ELECTRONIC MARKER-BASED NAVIGATION SYSTEMS AND METHODS FOR USE IN GNSS-DEPRIVED ENVIRONMENTS; U.S. patent application Ser. No. 17/528,956, filed Nov. 17, 2021, entitled VIDEO INSPECTION SYSTEM, APPARATUS, AND METHODS WITH RELAY MODULES AND CONNECTION PORT; U.S. patent application Ser. No. 17/541,057, filed Dec. 2, 2021, entitled COLOR-INDEPENDENT MARKER DEVICE APPARATUS, METHODS, AND SYSTEMS; U.S. patent application Ser. No. 17/541,057, filed Dec. 2, 2021, entitled VIDEO INSPECTION SYSTEM, APPARATUS, AND METHODS WITH RELAY MODULES AND CONNECTION PORT; U.S. Pat. No. 11,199,510, issued Dec. 14, 2021, entitled PIPE INSPECTION AND CLEANING APPARATUS AND SYSTEMS; U.S. Provisional Patent Application 63/293,828, filed Dec. 26, 2021, entitled MODULAR BATTERY SYSTEMS INCLUDING INTERCHANGEABLE BATTERY INTERFACE APPARATUS; U.S. Pat. No. 11,209,115, issued Dec. 28, 2021, entitled PIPE INSPECTION AND/OR MAPPING CAMERA HEADS, SYSTEMS, AND METHODS; U.S. Provisional Patent Application 63/306,088, filed Feb. 2, 2022, entitled UTILITY LOCATING SYSTEMS AND METHODS WITH FILTER TUNING FOR POWER GRID FLUCTUATIONS; U.S. Pat. No. 11,300,597, issued Apr. 12, 2022, entitled SYSTEMS AND METHODS FOR LOCATING AND/OR MAPPING BURIED UTILITIES USING VEHICLE-MOUNTED LOCATING DEVICES; U.S. Pat. No. 11,333,786, issued May 17, 2022, entitled BURIED UTILITY MARKER DEVICE, SYSTEMS, AND METHODS; U.S. patent application Ser. No. 17/845,290, filed Jun. 21, 2022, entitled DAYLIGHT VISIBLE AND MULTI-SPECTRAL LASER RANGEFINDER AND ASSOCIATED METHODS AND UTIITY LOCATOR DEVICES; U.S. Pat. No. 11,366,245, issued Jun. 21, 2022, entitled BURIED UTILITY LOCATOR GROUND TRACKING APPARATUS, SYSTEMS, AND METHODS; U.S. Provisional Patent Application 63/368,879, filed Jul. 19, 2022, entitled NATURAL VOICE UTILITY ASSET ANNOTATION SYSTEM; U.S. Pat. No. 11,397,274, issued Jul. 26, 2022, entitled TRACKED DISTANCE MEASURING DEVICES, SYSTEMS, AND METHODS; U.S. Pat. No. 11,402,237, issued Aug. 2, 2022, entitled VIDEO PIPE INSPECTION SYSTEMS WITH VIDEO INTEGRATED WITH ADDITIONAL SENSOR DATA; U.S. Pat. No. 11,418,761, issued Aug. 16, 2022, entitled INSPECTION CAMERA DEVICES AND METHODS WITH SELECTIVELY ILLUMINATED MULTISENSOR IMAGING SYSTEMS; U.S. Pat. No. 11,428,814, issued Aug. 30, 2022, entitled OPTICAL GROUND TRACKING APPARATUS, SYSTEMS, AND METHODS FOR USE WITH BURIED UTILITY LOCATORS; U.S. patent application Ser. No. 17/930,029, filed Sep. 6, 2022, entitled GNSS POSITIONING METHODS AND DEVICES USING PPP-RTK, RTK, SSR, OR LIKE CORRECTION DATA; U.S. Pat. No. 11,448,600, issued Sep. 20, 2022, entitled MULTI-CAMERA PIPE INSPECTION APPARATUS, SYSTEMS, AND METHODS; U.S. patent application Ser. No. 17/935,564, filed Sep. 26, 2022, entitled SYSTEMS AND METHODS FOR DETERMINING AND DISTINGUISHING BURIED OBJECT USING ARTIFICIAL INTELLIGENCE; U.S. Pat. No. 11,474,276, issued Oct. 18, 2022, entitled SYSTEMS AND METHODS FOR UTILITY LOCATING IN A MULTI-UTILITY ENVIRONMENT; U.S. Pat. No. 11,476,851, issued Oct. 18, 2022, entitled MAGNETICALLY SENSED USER INTERFCE DEVICES; U.S. Provisional Patent Application 63/380,375, filed Oct. 20, 2022, entitled LINKED CABLE-HANDLING AND CABLE-STORAGE DRUM DEVICES AND SYSTEMS FOR THE COORDINATED MOVEMENT OF A PUSH-CABLE; U.S. Provisional Patent Application 63/435,148, filed Dec. 23, 2022, entitled SYSTEMS, APPARATUS, AND METHODS FOR DOCUMENTING UTILITY POTHOLES AND ASSOCIATED UTILITY LINES; U.S. patent application Ser. No. 18/162,663, filed Jan. 31, 2023, entitled UTILTY LOCATING SYSTEMS AND METHODS WITH FILTER TUNING FOR POWER GRID FLUCTUATIONS; U.S. Provisional Patent Application 63/492,473, filed Mar. 27, 2023, entitled VIDEO INSPECTION AND CAMERA HEAD TRACKING SYSTEMS AND METHODS; U.S. Pat. No. 11,649,917, issued May 16, 2023, entitled INTEGRATED FLEX-SHAFT CAMERA SYSTEM WITH HAND CONTROL; and U.S. Pat. No. 11,665,321, issued May 30, 2023, entitled PIPE INSPECTION SYSTEM WITH REPLACEABLE CABLE STORAGE DRUM. The content of each of the above-described patents and applications is incorporated by reference herein in its entirety. The above applications may be collectively denoted herein as the “co-assigned applications” or “incorporated applications.”The following exemplary embodiments are provided for the purpose of illustrating examples of various aspects, details, and functions of devices, apparatus, and systems; however, the described embodiments are not intended to be in any way limiting. It will be apparent to one of ordinary skill in the art that various aspects may be implemented in other embodiments within the spirit and scope of the present disclosure.

It is noted that as used herein, the term, “exemplary” means “serving as an example, instance, or illustration.” Any aspect, detail, function, implementation, and/or embodiment described herein as “exemplary” is not necessarily to be construed as preferred or advantageous over other aspects and/or embodiments.

### Example Embodiments

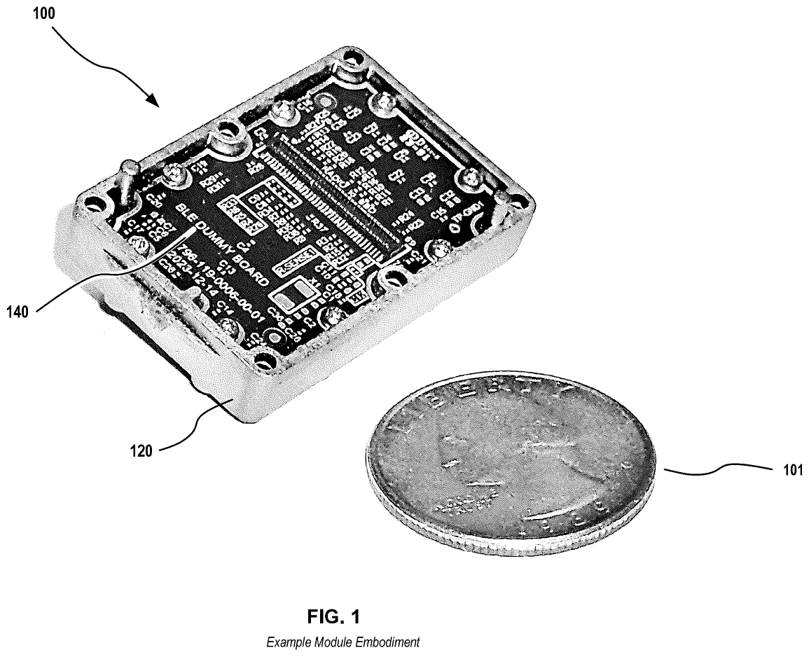

FIG. 1 illustrates an exemplary electronics module embodiment 100 (also referred to herein as just a “module” for brevity). Module embodiment 100 is in the form of a Bluetooth™M wireless transceiver module, however, various other electronic circuitry can be implemented on alternate module embodiments in accordance with aspects of the disclosure and in applications such as those described previously herein, as well as other devices and applications.

Module 100 comprises a housing 120 (which can function as a case or shield as well as a mechanical mounting mechanism for other module components) as well as an electronic printed circuit board or boards 140 (also denoted herein as a “PCB” for brevity). As noted above in the example of FIG. 1 the electronic circuit on PCB 140 implements a Bluetooth transceiver, however, any of various other electronic circuits or combinations of circuits and/or other elements may be implemented in different module embodiments.

A United States quarter dollar is also shown in FIG. 1 to illustrate the relative size of an exemplary module embodiment. It is noted, however, that alternate embodiments may be implemented in larger or smaller sizes, as well as different shapes, shielding configurations, included electronic circuit or circuits, additional elements such as mechanical components, optical components, electromagnetic components, and the like may also be included.

In exemplary module systems, it may be desirable to define a standard module shape, size, connector pinout(s), and other parameters to facilitate ready interchangeability and/or manufacturability of associated systems in which such modules are placed. Some examples of this are described subsequently herein in conjunction with the drawing figures.

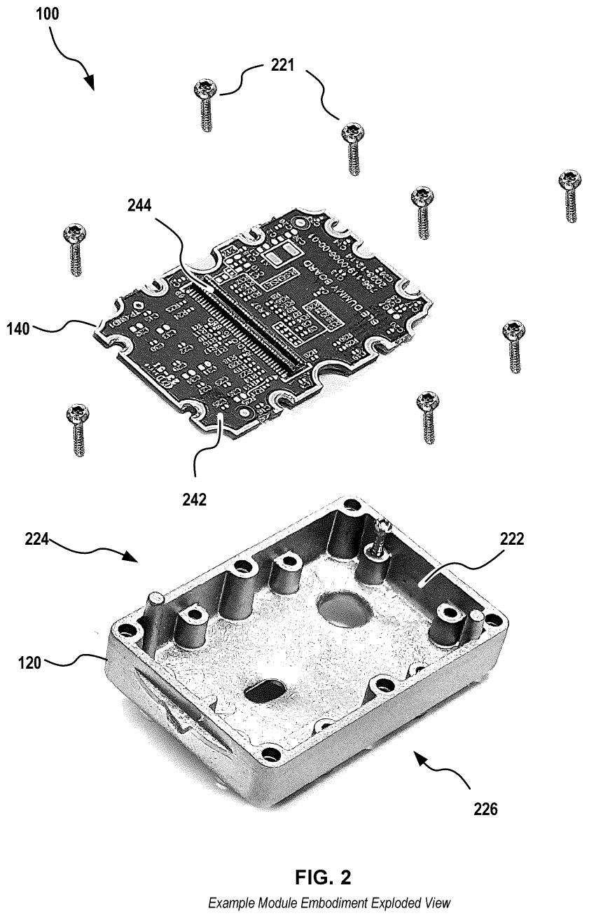

FIG. 2 illustrates additional details of module embodiment 100 in an exploded or disassembled view. PCB embodiment 140 may be a circuit board and associated components that are mounted in housing 120 using, for example, screws 221 or other attachment mechanisms (i.e., in this example eight screws are used, however, other embodiments may use different number of screw or other attachment mechanisms in different configurations). PCB embodiment 140 may implement any of various types of electronic circuitry or functions, such as wireless transceivers, signal processing circuits, analog circuitry, microprocessor circuitry, and/or other types of electronic circuits or hybrid electronic, optical, and/or mechanical functions.

PCB embodiment 140 may include one or more circuit boards, such as printed circuit board (“PCB”) 242 as shown, as well as one or more electronic, electromechanical, optical, or other components on the PCB, as well as electrical connectors, such as connector 244 as shown in FIG. 2, to couple electronic signals and/or power to or from the electronic circuit board, as well as other electrical, mechanical, or optical components or assemblies. Some embodiments may include optical connectors to couple fiber optic cables to the PCB and/or other types of connectors as are known or developed in the art.

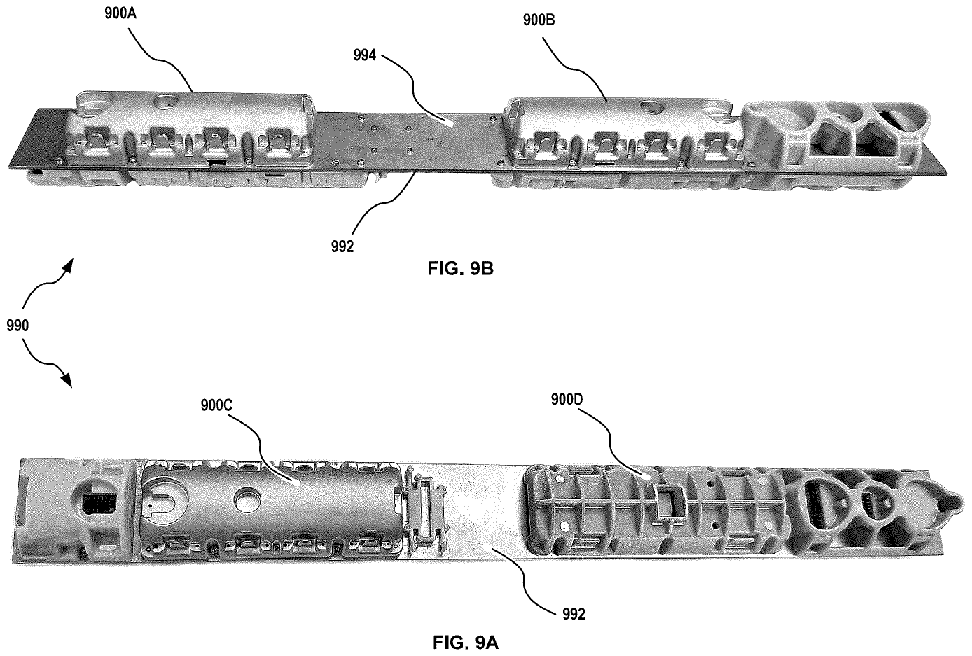

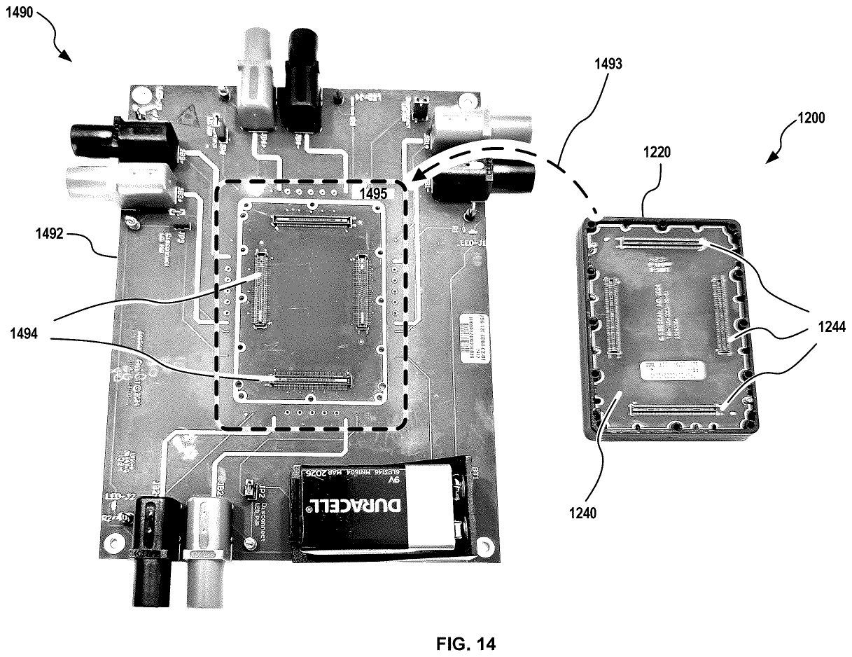

In exemplary embodiments, modules may be configured based on defined standard connector types and locations so as to allow for interconnectivity of different module types within a system using the same connector or connectors. Examples of this are described subsequently herein with respect to, for example, FIG. 9A and FIG. 9B as well as FIG. 14 (where module embodiments are mounted or mountable on other electronic device circuit boards or assemblies).

The PCB and/or housing of various module embodiments may include mechanical features to facilitate fast and accurate registration of electronic connector(s) to associated interfaces such as cables with matching pinouts, additional connectors, or other electronic interface elements such as are described subsequently herein.

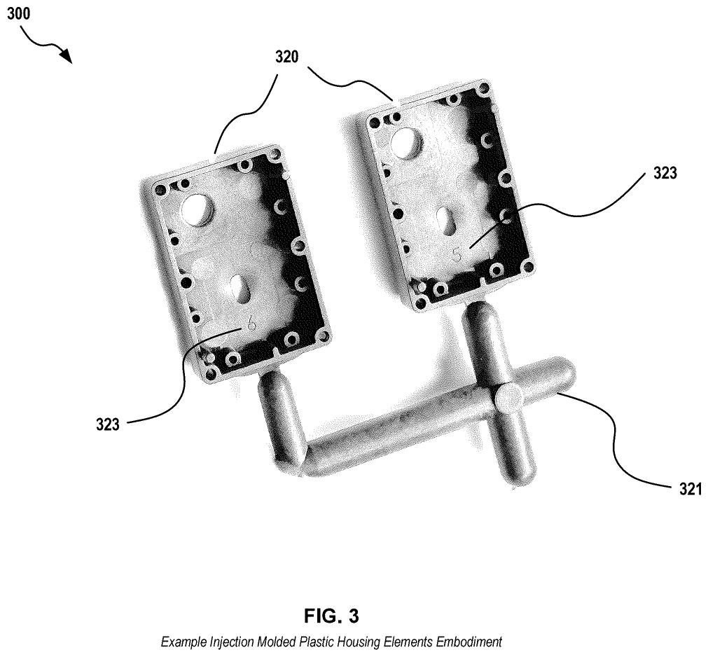

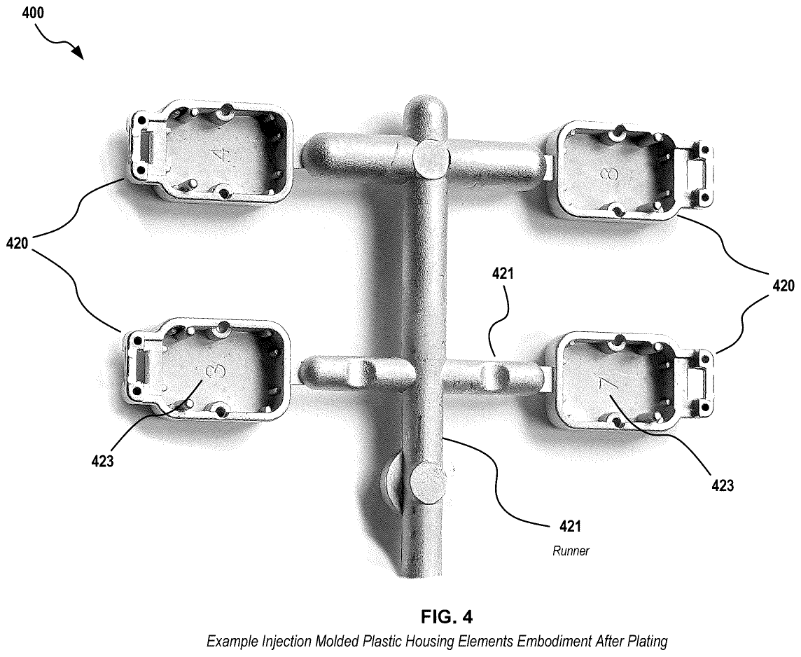

Exemplary module housings, such as housing embodiment 120 as shown in FIGS. 1 and 2, may be formed or created by injection molding of plastic resin materials such as shown in FIG. 3 and FIG. 4 and as described subsequently herein.

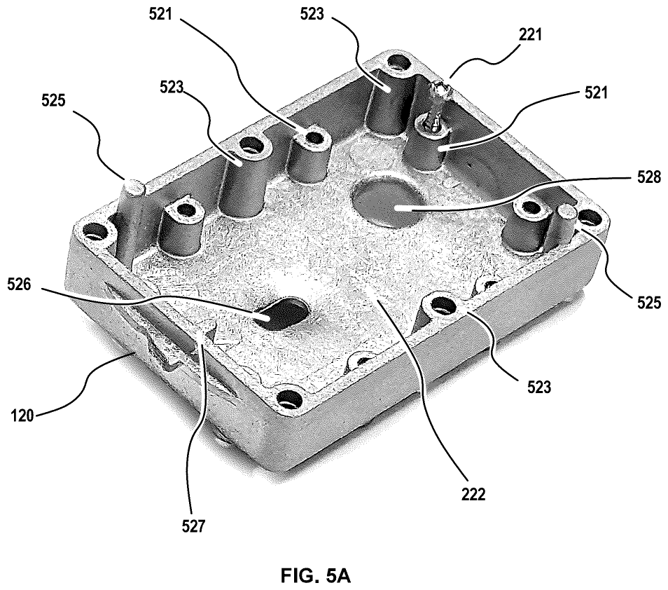

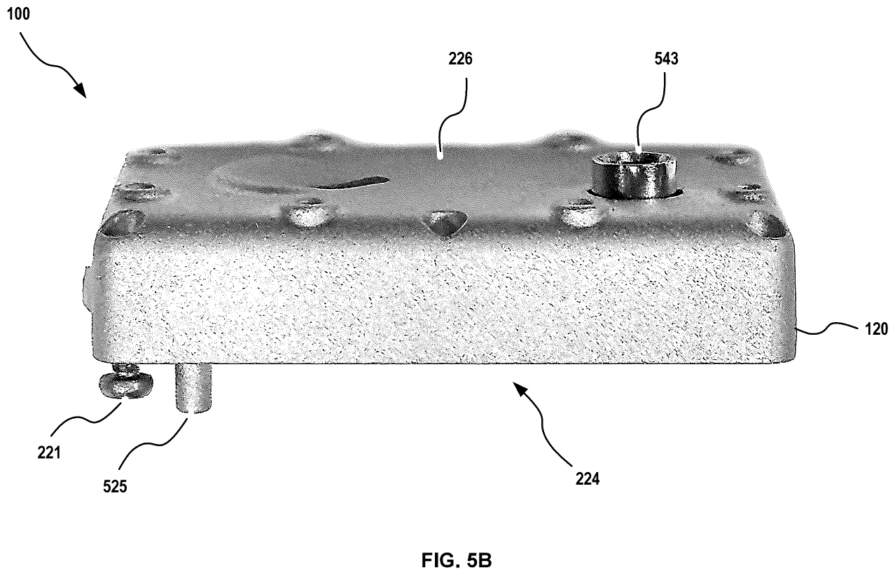

Referring again to FIG. 2, housing embodiment 120 may include an interior volume 222, in which circuit board such as PCB 140 and/or other components may be installed or placed. The housing embodiment may have a top or upper side 226 (underneath the housing embodiment 120 as shown in FIG. 2 and also shown on the top in FIG. 5B) which may be solid or may include holes or other openings such as shown in FIG. 2. The housing embodiment may also have a bottom or lower side 224, which is open in the embodiment as shown in FIG. 2, but may include a cover or may be positioned adjacent a circuit board or other electronics component or assembly in various assembly and device embodiments (e.g., as shown in, for example, FIG. 9A and FIG. 14).

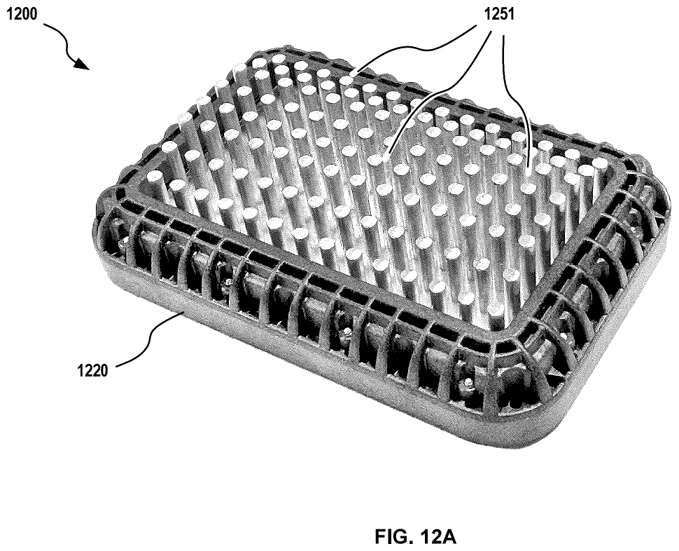

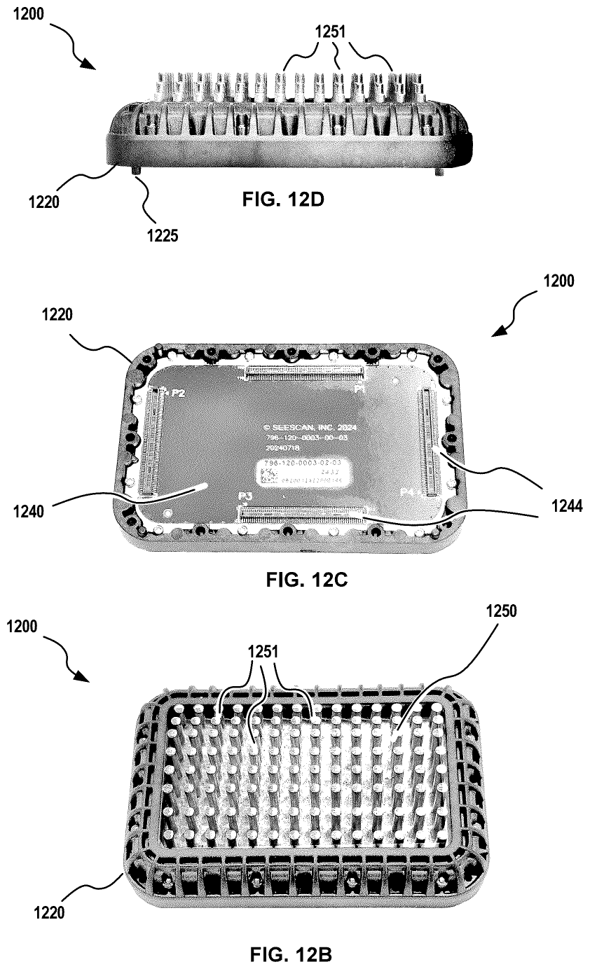

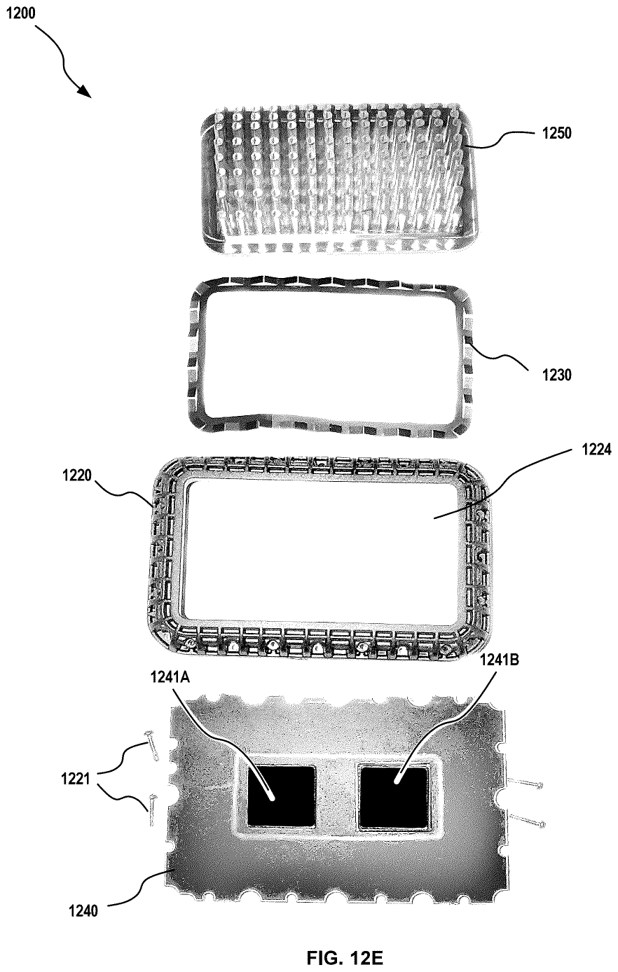

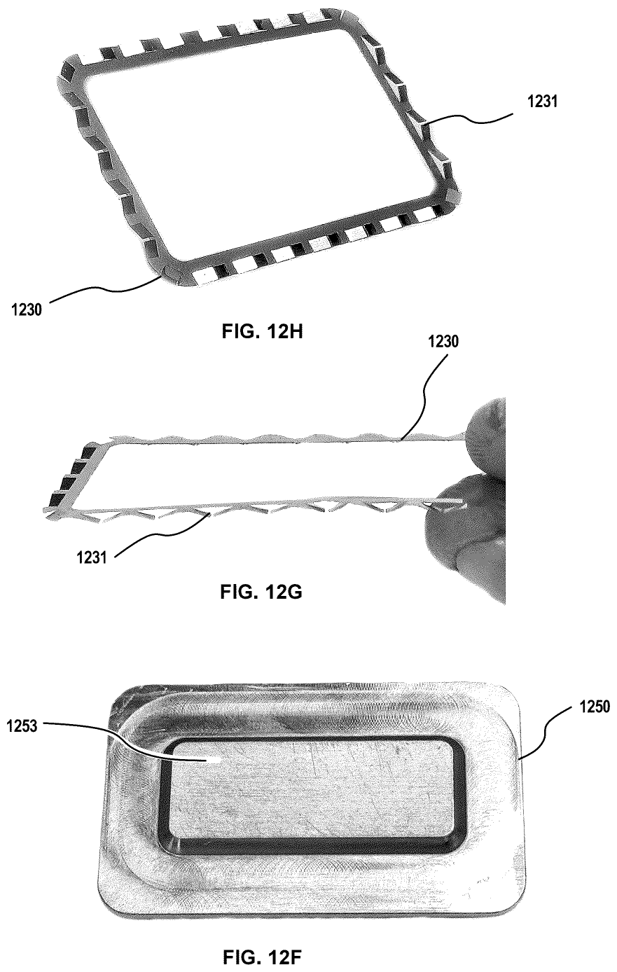

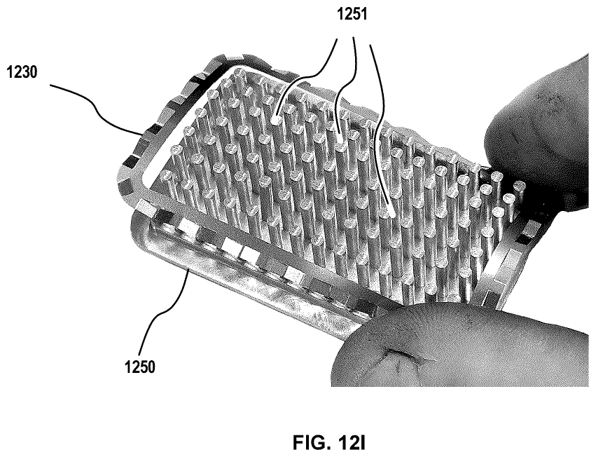

In an exemplary embodiment, a housing such as housing embodiment 120 may be molded or otherwise formed or made in a rectangular box-like shape as shown in FIG. 2. The housing may have an open lower or bottom side and a solid upper or top side as shown. Some embodiments may have an opening on the upper or top side to allow a heat sink to be placed in the opening, such as, for example, is shown in FIG. 12A.

In alternate embodiments, rather than being injection molded from a plastic or polymer material, a module housing may be die-cast, vacuum formed, or manufactured using other current or future-developed manufacturing technologies and materials.

I some other embodiments a housing may have alternate shapes, such as cylindrical, spherical, or other shape configurations, dimensions, and/or proportions.

In manufacturing housing embodiments, it may be advantageous to injection mold them from a plastic or polymer (or other relevant material) and leave them on an injection molding runner system during the manufacturing process before singulating (i.e., separating the parts) the individual housings. This may be done, for example, to minimize handling of individual housings (and reducing associated defects or damage) or for other reasons. For example, by leaving all of the individual housing elements on the runner system a worker can grab the runner system to hold multiple elements (e.g., eight in an exemplary embodiment) while working with them. This may simplify optional additional manufacturing steps, such as plating of the modules, by allowing easier handling of the modules through the plating process, simplifying the overall process by plating (or otherwise processing) the individual parts before singulation.

One example of this is shown in FIG. 3, which illustrates two injection molded modules left on their runners in an example multiple housing array embodiment 300. Housing array embodiment 300 includes injection molded housing elements 320, with the individual elements 320 shown attached to typical injection molding runners 321, allowing for making multiple housing elements on a single mold.

In some embodiments, such as array 300 as shown in FIG. 3, the individual housing elements 320 may include numbering, such as numbers 323 as shown, or other markings or indicators to uniquely identify each housing element. Marking using numbers as shown in FIG. 3 may be use to show, for example, where in the mold each individual housing was molded, as well as other information such as a serial number of the mold they were formed on (not shown in FIG. 3).

As one example advantage of such marking, the numbering may be used during later testing to facilitate identifying problems with a mold (e.g., if multiple parts fail and they have the same number it may be indicative of a mold cavity problem on that particularly numbered cavity).

In exemplary embodiments a plateable resin may be used to make the housings. The individual housing elements may be then be plated (for example, while left on the array as shown in FIG. 3 and FIG. 4 or, in some embodiments, after separating them from the mold runners or other structures) for electromagnetic shielding, or for other reasons such as increased structural characteristics, insulating characteristics, conductivity characteristics, and the like using, for example, highly conductive metals such as copper, gold, silver, and/or other conductive or shielding materials.

By forming the housing elements with injection molding, plating of multiple housings may advantageously be done simultaneously, such as shown in multiple housing array embodiment 400 as shown in FIG. 4. Similar to housing array embodiment 300 shown in FIG. 3, housing array embodiment 400 includes multiple molded individual housing elements 420 along with typical runners 421. Modules 420 also include mold numberings 432. Modules 420 of array 400 as shown in FIG. 4 are plated with a highly electrically conductive surface layer around the entirely of the module to provide shielding, low resistance connectivity to PCBs or other module elements, low resistance mechanical connections (e.g., to screws or other mechanical assembly components) and the like.

When using plateable resins, all or part of housing array embodiment 400 may be plated as part of the manufacturing process. For example, depending on the molding and plating used, in some embodiments the entire array may be plated such as shown in FIG. 4. In other embodiments only part of the array may be plated; for example, only the individual housing elements may be plated, or in some embodiments only portion of the individual housing elements may be plated (not shown in FIG. 4).

In an exemplary embodiment the resin may comprise about 40 (forty) percent carbon fiber-filled Ultem resin (Ultem is a trademark for amorphous thermoplastic polyetherimide (PEI) material, see, e.g., https://www.sabic.com/en/products/specialties/ultem-resin-family-of-high-heat-solutions/ultem-resin). Use of carbon fiber makes the housing elements somewhat conductive.

In some embodiments the housing may be primarily or entirely metallic. For example, metal injection molding may be used or other metal fabrication methods may be used such as 3D printing, die cast, powdered metal laser sintered, and the like. In some of these alternately embodiments such as these metal housings may also be plated with metals or other materials.

FIG. 5A illustrates additional details of the housing embodiment 120 as shown in FIG. 1 and FIG. 2. Housing embodiment 120 may include one or more PCB mounting bosses 521 as shown. These may be located along the ends, sides, or other positions, such as within the interior volume 222 of the housing. For example, in the embodiment shown in FIG. 5 two PCB mounting bosses 521 as shown on each of the four interior sides of the housing.

PCB mounting bosses may have their top sides recessed from the top of the housing as shown to allow a PCB or other mounted element of the module to sit at or below the top side surface of the housing, such as shown in FIG. 1 (slightly below the top surface in the example housing 120 in FIG. 1). In other embodiments various alternate numbers, sizes, and positions of PCB or other interior mounting bosses may be used depending on the number of circuit boards or other module configurations.

Additional mounting bosses may be used in various embodiments. For example, housing mounting bosses 523 may be included in the housing to facilitate attachment of the module to other system components, such as other circuit boards, mechanical assemblies, or other mounting places and positions within a module or associated apparatus or device. In example embodiment 120 as shown, two housing mounting bosses 523 are formed on the shorter sides of the housing with their top sides flush with the lower or bottom side, and three housing mounting bosses 523 are on the longer sides also flush with the lower or bottom side. In alternate housing embodiments different numbers, sizes, recesses from the lower or bottom side, and/or shapes of housing mounting bosses may be included.

Housing embodiments may include alignment pins or posts such as keying or alignment posts or pins 525 as shown in FIG. 5. These posts may be used to align the modules with other external system components such as other circuit boards, and/or with other components positioned in the interior volume of the housing or external to the housing.

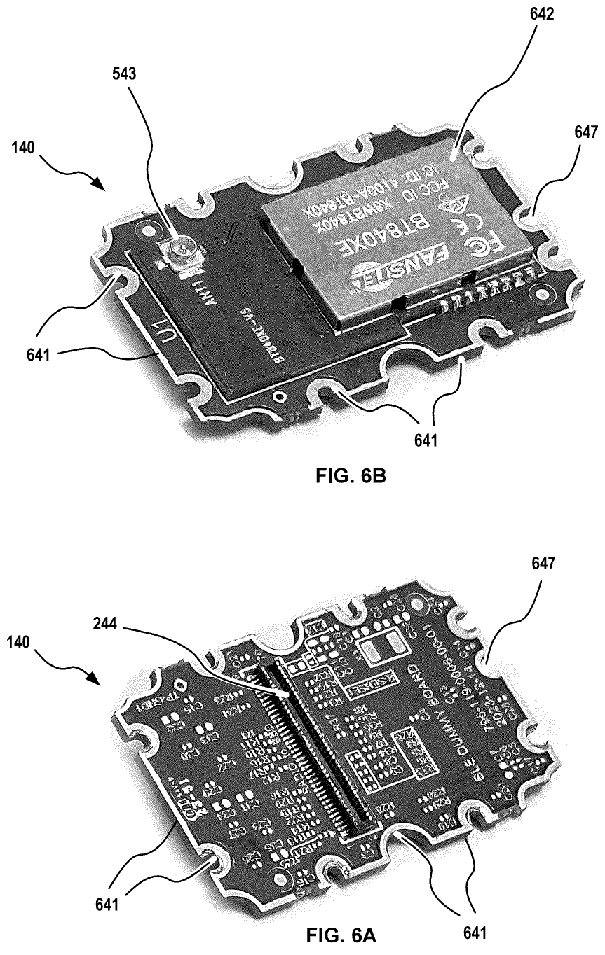

Housing embodiments may include one or more keying ribs to facilitate alignment of components placed in the housing interior volume 222, such as keying rib 527 as shown in FIG. 5. Keying rib 527 protrudes from a side of the housing into the interior volume to engage a corresponding void in a component positioned within the volume, such as with correspondingly shaped opening 647 of PCB 140 as shown in FIG. 6A and FIG. 6B.

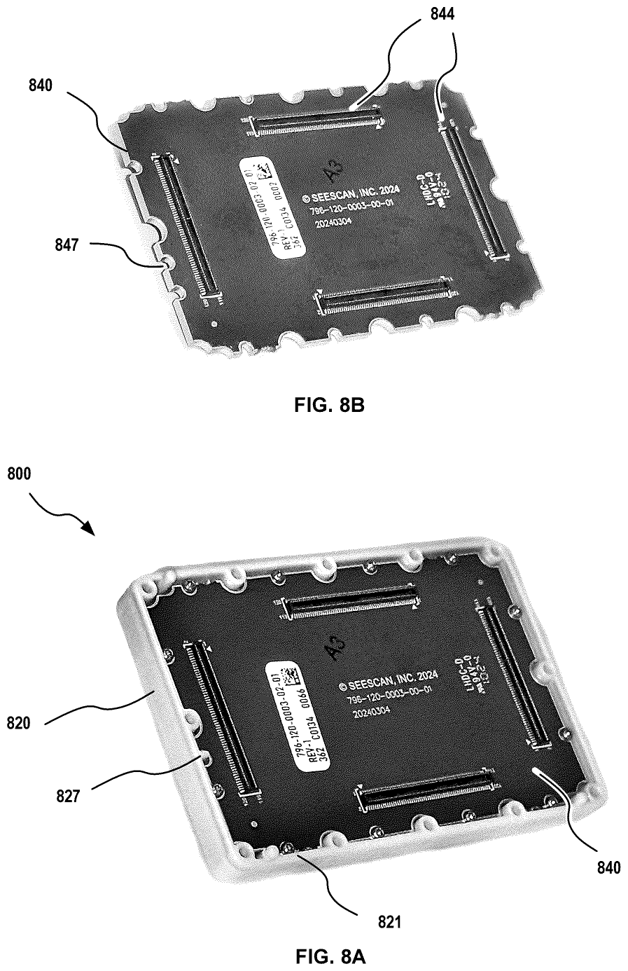

Similar functionality to the engagement of keying rib 527 and PCB opening 647 is shown in the alternate module embodiment 800 of FIG. 8A (with keying rib 827 and keying opening 847 of FIG. 8A). This keying and associated opening configuration may be used to prevent insertion of a PCB into a housing during assembly either upside-down or right-left reversed.

Additional keying mechanisms, such as keying pin 525, may be included to allow for registration with another element to which the module is attached, such as to another circuit board or other assembly or device element (e.g., a frame, other housing, additional PCB, and the like). This can aid in placing a module accurately within other assembly or device elements using standardized, predefined circuit board and connector layouts and associated mechanical configurations. Alternate embodiments may use ribs or other registration elements (Not shown) to facilitate keying of modules with other system elements.

Housing embodiments may include one or more holes or opening for components, cables, connectors, heat sinks, or other elements to pass-through. For example, housing embodiment 120 includes an opening 526 (as shown in FIG. 5A) for pass-through connections to a U.FL (ultra-small, Hirose) connector, as well as opening 528 for pass-through or admitting an FCX connector.

Alternate module embodiments may include openings of other shapes, sizes, positions, and the like depending on pass-through needs for wires or components of the associated module.

FIG. 5B illustrated module embodiment 100 from a side view, with the upper or top side 226 of housing embodiment 120 shown on the top of the figure, and screws 221 securing PCB embodiment 140 inside of housing 120 (as such, PCB 140 is not visible). An antenna jack may be included, such as jack 543 which can be seen protruding from the back side of housing 120. The antenna jack or connector 543 (an FCX connector in the embodiment shown) may be used to, for example, position a Bluetooth, Wifi, or other antenna outside of the shielded volume with the module 100.

Antenna jack 543 is further illustrated in FIG. 6B on PCB embodiment 140, with the connector 543 passing through opening 528 as shown in FIG. 5A. Keying pin embodiment 525 is shown protruding from the front side 224 of housing 120 in FIG. 5B, and keying or other registration elements such as this may be used to properly align a module to another element such as another circuit board, frame, or other element of a system in which the module is installed.

FIG. 6A and FIG. 6B illustrate additional details of the PCB embodiment 140 as shown in FIG. 1 and FIG. 2. FIG. 6A illustrates the lower or bottom side of the PCB embodiment 140 (facing towards the open bottom of housing 120), and FIG. 6B illustrates the top or upper side of the PCB (facing towards the enclosed top side of the housing.

As noted previously, this example PCB embodiment 140 implements a BLE (Bluetooth Low Energy) circuit, however, the elements and functions described below may be implemented on electronic circuit of various types, sizes, and shapes in alternate embodiments.

As this embodiment 140 is a radio module, an antenna jack or connector 643 as described previously herein may be soldered to the PCB 140 or, in other embodiments, may be mounted on alternate PCBs or other connector or jack elements of a circuit.

PCB embodiments, such as embodiment 140 or other embodiments described subsequently herein, may include a ground plane or other conductive surface or volume with the plane flooded into a perimeter (or other) area, such as perimeter flood area 641 as shown in FIG. 6A and FIG. 6B. This conductive surface allows for a low resistance electrical contact between the flood area and the plated housing through use of screws, such as screws 221, through the flood area (or other conductive area) of PCB embodiment 140 to the housing 120, with the screws tightened sufficiently to provide a strong mechanical and electrical contact from the PCB to the plating of the housing.

Use of multiple screws may further improve the electrical contact between the housing and the PCB (or other internal housing component) by reducing resistance and/or path length, and may also be used to shape the shielding and ground profile of the module. In addition, if the housing is plated with an appropriate metal or other conductive material, solder connections can be made directly between surfaces of the housing and solderable areas of the PCB, or between the module and other assembly or device electrical connection points.

In exemplary electronic modules, one or more electrical connectors may be used to operatively couple the module to associated assembly or device power and/or signal connections. For example, PCB embodiment 140 may include one or more electrical connectors, such as connector embodiment 240 as shown in FIG. 2 and FIG. 6, or other connector embodiments as described subsequently herein.

The PCB or other module connector or connectors may be positioned in a standardized defined position, such as a predefined standardized position on the PCB, so as to facilitate upgrading of the module with newer or alternate versions while maintaining a predefined mechanical position and electrical pinout. Using a predefined standardized connection position may also facilitate easy mounting of electronic modules on other assembly or device elements, such as additional circuit board as shown in, for example, FIG. 14, wherein module embodiment 1200 may be mounted to PCB 1492 of assembly 1490. Module 1220 mounts with its connectors 1244 attached to corresponding connectors 1494 of PCB 1492, with the module itself positioned with the dashed lined area 1495. PCB traces on PCB 1492 and PCB 1240 of module 1220 may be in tight contact to electrically couple the two areas and provide shielding completely around PCB 1240.

Connector 240 has a mechanical interface defined by its position on the PCB and relative to the housing and with respect to any keying or registration elements of the housing, as well as an electrical interface defined by the pinout, and a software interface defined by any associated APIs (application programming interfaces) or other software-defined interfaces. By standardizing these interfaces, modules of various types may be readily placed on other device or apparatus elements and/or readily interchanged with new or different modules with upgraded or different functionality.

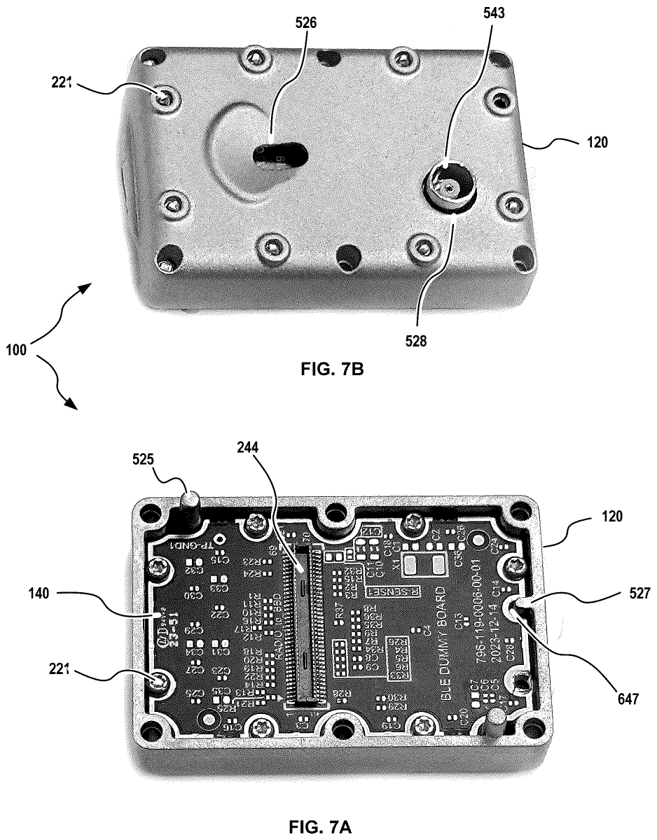

FIG. 7A and FIG. 7B illustrate additional details of module embodiment 100 as assembled from the front or to side (FIG. 7A) and back or bottom side (FIG. 7B) of housing 140.

As shown in FIG. 7A, PCB 140 is mechanically and electrically bonded to plated housing 120 through direct contact with a boss on the housing (not shown in FIG. 7A, but illustrated in FIG. 5A as one of the bosses 521) as well as through contact with conductive screw 221 from the solder flooded area of PCB 140 to the plating of the boss (and housing itself if the housing is formed of metal or other conductive materials such as conductive resins) and through the plated back side of housing 120 as shown in FIG. 7B. PCB 140 is keyed to housing 120 through rib 527 of housing 120 and hole 647 of PCB 140. Connector 244 is positioned in a defined position within the module and module registration elements, such as pin 525. FIG. 7B shows the back or bottom side of housing 120, with antenna connector 543 passing through hole 528. As shown, there is no connector in opening 526, however, opening 526 may be molded as shown to receive a U.FL connector (as shown) or other connector type or opening in alternate embodiments (not shown).

FIG. 8A illustrates details of the bottom or lower side of a module embodiment 800. Module embodiment 800 includes four connectors 844 on PCB embodiment 840, rather than the single connector 244 as shown in module embodiment 100. Various other embodiments may include fewer or more connectors than those shown module embodiment 100 and module embodiment 800, and those connectors may be of different types and/or sizes and may be placed in other positions on corresponding PCBs or other circuit connection elements.

FIG. 8B illustrates additional details of PCB embodiment 840, including registration void or cutout 847, which may be included to correctly register the position of the PCB 840 within housing embodiment 820 as shown in FIG. 8A. One or more screws 821 may be used to attach PCB 840 to housing 820 as shown in FIG. 8A.

FIG. 9A and FIG. 9B illustrate an example assembly embodiment 990 which includes four modules 900A to 900D. These modules may be the similar to the modules described previously or subsequently herein. Assembly 990 is an example buried utility locator circuit board assembly, illustrating how modules such as those described herein may be used to simplify construction of the assembly, as well as to reduce size, facilitate various shapes of assemblies (in this example, a locator typically includes a round, elongate mast assembly into which assembly 990 may be positioned), standardize system components, and provide other advantages.

Some module embodiments may include heat sinks or other features to facilitate cooling of the modules, particularly when PCT circuit elements such as integrated circuits (“ICs”) generate significant hear that need to be removed from the area around the PCB or from within volumes in the electronic device in which the module is placed.

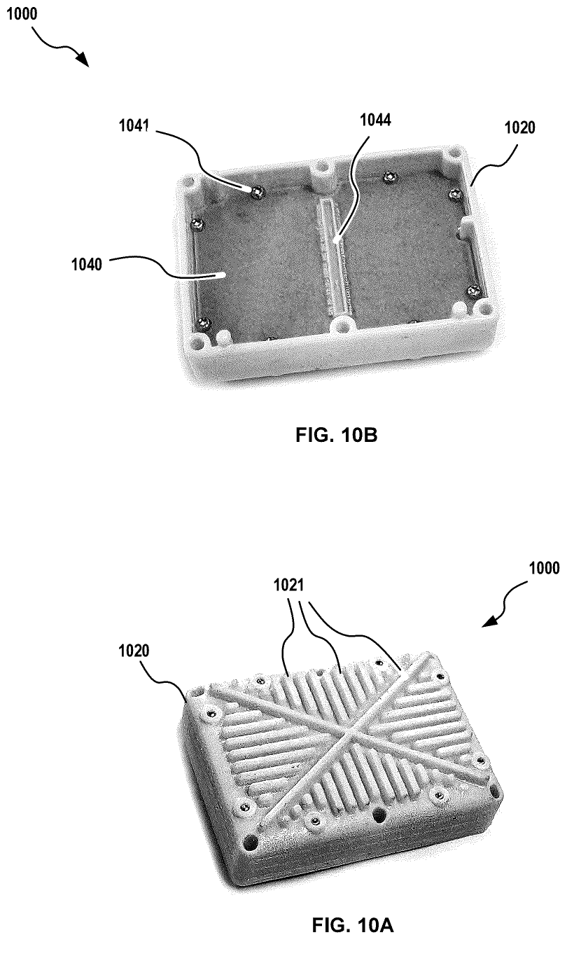

FIG. 10A and FIG. 10B illustrate one exemplary module housing configuration to enhance heat dissipation. As shown in FIG. 10B, module 1000 includes a housing embodiment 1020, a PCB embodiment 1040, with the PCB 1040 including an electrical connector 1044, and screws 1041 to attach the PCB 1040 to the housing 1020. Additional elements and features as are described elsewhere herein with respect to various module embodiments may also be include in module 1000 (not shown in FIG. 10A and FIG. 10B).

While module embodiments as described previously herein may facilitate heat dissipation with plating on housings, openings in housings, and other thermal conductive pathways, in some embodiments a module housing may include fins or other heat dissipation structures to increase the surface area of the module so as to facilitate increased heat flow to the exterior. For example, Housing embodiment 1020 of module embodiment 1000 includes multiple cooling fins 1021 to increase the heat dissipation area of the housing. In exemplary embodiments the cooling fins (or other heat dissipation structures) may be directly molded in the housings (i.e., by being part of the mold features), or in alternate embodiments may be machined or otherwise formed in the housing.

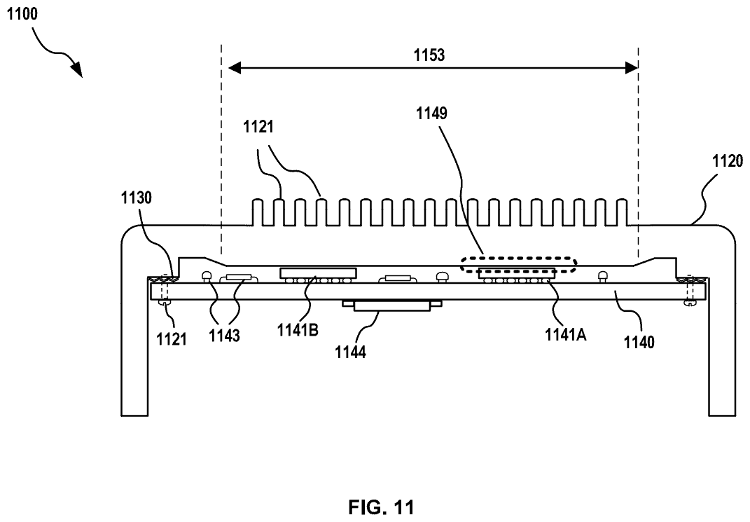

FIG. 11 illustrates details of a module embodiment 1100 including integral cooling fins shown in a cutaway view from side. Module 1100 includes a housing 1120, with the housing including a plurality of fins 1120, as well as a PCB embodiment 1140 positioned within the housing 1120. The PCB 1140 is recessed from the bottom side of the housing (shown on the lower area of FIG. 11) similar to the recessed configuration of PCB 1040 in housing 1020 of FIG. 10B.

PCB 1140 may include various electronic components such as, for example, resistor and capacitors 1143, one or more ICs, such as IC 1141A and 1141B, as well as one or more electrical connectors, such as connector 1144.

Heat dissipation is often most important from circuit elements such as ICs 1141A and 1141B, and as such it may be desirable to place these components in close proximity or in direct contact with the housing and associated cooling fins. For example, ICs 1141A and 1141B may be in direct contact with the inner side of housing 1120 as shown in FIG. 11. In some embodiments, heat conductive paste or other heat conductive materials, may be placed in the dashed area 1149 between IC1141A and housing 1120 to enhance thermal conductivity between the IC and the housing and associated cooling fins 1121. In some embodiments, the housing may include a thicker section or sections in the area where enhance heat dissipation is desired. One implementation of this is the thicker volume of the housing 1120 as defined between the ramped down thicker housing volume defined between the dashed lines at the ends of arrow 1153. An alternate embodiment of such a thickened contact volume and surface area is illustrated in FIG. 12F as area 1253 (in the example of FIG. 12F this area is on a heat sink, but a similar configuration may be molded into an integral heat sink housing such as shown in FIG. 10A and FIG. 11, or may be glued or otherwise formed or attached to the housing).

In some embodiments it may be desirable to control the loading between the housing and other module elements. For example, it may be desirable to limit the force between ICs 11411A and 1141B and the housing 1120. This may be implemented by, for example, using a spring, such as spring 1130, positioned between the housing and PCB, to control tightness by allowing for adjustment of torque applied to PCB mounting screws, such as screws 1121. Such a spring configuration may be similar to the configuration and functionality of a spring washer or similar element. Additional details of example spring embodiments for torque adjustment are shown in FIG. 12G and FIG. 12H and are described subsequently herein.

An alternate embodiment to the integral heat link housing embodiment shown in FIG. 10A is to include a heat sink separate from the housing itself. In this configuration the housing may have an opening on the top or upper side through which all or part of the heat sink may pass through.

For example, FIG. 12A illustrates one exemplary embodiment of this configuration in the form of electronic module embodiment 1200. Module 1200 includes a housing 1220, as well as a PCB 1240 (shown in FIG. 12C and FIG. 12E), and a heat sink 1250 (shown in FIG. 12B and FIG. 12E). The heat sink may include cooling fins or other elements to increase surface area to facilitate heat dissipation. For example, heat sink 1250 includes multiple cooling fins or stubs 1251 as shown in FIG. 12A. These fins protrude through an opening 1224 (shown in FIG. 12E) on the top side of housing 1220 to facilitate dissipation of heat generated in the interior volume of module 1200.

FIG. 12B illustrates module embodiment 1200 as seen from the upper or top side, showing fins 1251 protruding from the top of housing 1200. In some embodiments the fins may be positioned below the top of the housing rather than protruding from it as shown in FIG. 12B, depending on the available clearance and/or other constraints on module size or position.

FIG. 12C illustrates module embodiment 1200 as seen from the lower or bottom side, showing positioning of PCB embodiment 1240 within housing 1200, as well as multiple electrical connectors 1244 on PCB 1240. PCB 1240 may be same as or similar to PCB 840 as described previously herein and may share elements and features of the other PCBs described herein in various embodiments.

FIG. 12D illustrates module embodiment 1200 from a side view, further illustrating cooling fins 1251 extending about the top side of housing 1220. Alignment pins or posts 1225 may be included in housing 1220 to facilitate mounting and alignment of the module 1200 with other assemblies or devices.

It is noted that other housing and PCB embodiment element and features as described elsewhere herein, such as, for example, posts, pins, ribs, cutouts, connectors, jacks, and the like may be included in various module embodiments such as module 1200 or other module embodiments (not shown) within the spirit and scope of the disclosure.

FIG. 12E illustrates various components of the module embodiment 1200 in exploded or disassembled view. These include housing embodiment 1220, which may include an open area 224 on the top or upper side to allow dissipation of heat via heat sink embodiment 1250, which may protrude through the opening as described previously herein. Module 1200 may include one or more PCBs, such as, for example, PCB 1240, which may include various electronic circuit components (not shown) as well as one or more ICs, such as ICs 1241A and 1241B as shown. Screws or other attachment mechanisms, such as screws 1221, may be used to attach the PCB to the housing.

As described previously herein, it may be desirable to control the loading between the PCB and the housing or other elements, such as between the PCB and a heat sink. This may be particularly important when heat generating components such as ICs are placed against the heat sink so as to avoid crushing the ICs, damaging or destroying them. A spring mechanism such as spring embodiment 1130 as described previously with respect to FIG. 11, may similarly be used to control torque between the PCB and heat sink.

FIG. 12G and FIG. 12H illustrate additional details of spring embodiment 1230. The spring embodiment may comprise a spring plate or other spring mechanism. FIG. 12G illustrates spring 1230 from a side view, showing the cut and bent edge sections 1231 of the spring that provide spring action through their flexure when tightened. These springs may be made of a metal or other material that provides restorative spring action. To facilitate heat dissipation the springs may be made of a high thermal conductivity material and/or a high electrical conductivity material to provide electromagnetic shielding. In some embodiments the springs may be plated or otherwise coated with materials to enhance conductivity or mechanical properties. Other spring configurations may also be used in alternate embodiments.

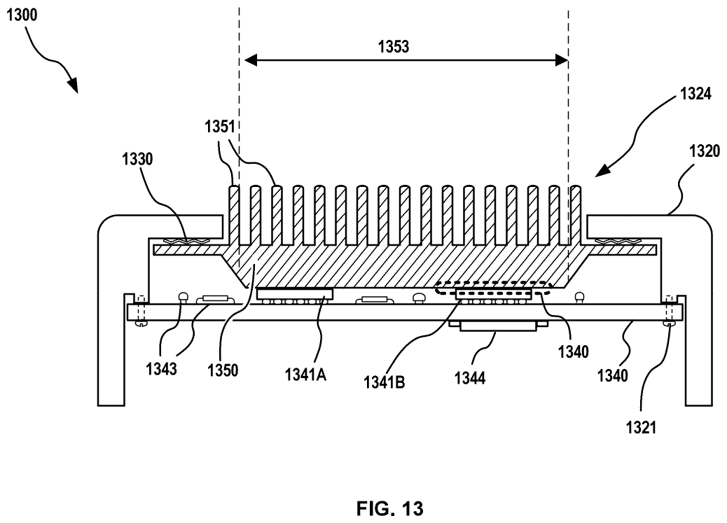

FIG. 12F illustrates the lower or bottom facing side of heat sink embodiment 1250. The heat sink may include a thicker area, such as area 1253, to provide thermal contact with ICs or other heat dissipation components of PCB 1140. FIG. 13 illustrates a similar thicker area of heat sink 1350 to facilitate contact with ICS or other heat generating elements or heat conductive elements (thickened area is shown between the dashed lines at either end of arrow 1353).

FIG. 12I illustrates the positioning of spring embodiment 1230 and heat sink 1250 prior to placement of heat sink 1250 into housing 1220. As assembled in module 1200, the spring 1250 is between the top or upper side of heat sink 1250 and the housing 1220. Spring 1230 may be placed between PCB 1240 and heat sink 1250 and the torque may be adjusted through tightening of screws 1221 to a desired torque level. A similar configuration is illustrated in FIG. 13 and described subsequently herein.

FIG. 13 illustrates a module embodiment 1300 including a housing embodiment 1320, a spring embodiment 1330, a PCB embodiment 1340, and a heat sink embodiment 1350. Module 1300 and its associated element embodiments may be similar to module 1200 and may include various elements and features as described elsewhere herein with respect to various other embodiments. Module embodiment 1300 may be similar to module embodiment 1200, with the additional of a separate heat sink element rather than the integral module heat sink configuration of embodiment 1200.

Housing embodiment 1300 may include an opening 1324 on the top side which may be the same as or similar to opening 1224 of housing 1220 as shown in FIG. 12E. Heat sink embodiment 1350 may include fins 1351 or other structures to increase heat dissipation surface area.

PCB embodiment 1340 may include various electronic components 1343 as well as one or more ICs or other heat generating elements such as ICs 1341A and 1341B. The ICs (or other heat generating elements, not shown) may be positioned in close proximity to or in contact with heat sink embodiment 1350, such as in the thicker area between the dashed lines on FIG. 13. Thermally conductive paste or other heat conduction mechanisms may be positioned in the area 1341B between the top of ICs 1341 and the bottom of heat sink 1350.

As with module embodiment 1200, loading between the PCB and heat sink, for example, at the contact points between ICs 1341A and 1341B, may be adjusted by tightening screws 1321 with a torque wrench, which compresses spring 1330 between housing 1320 and heat sink 1350.

The physical dimensions of module 1200, as reflected by housing 1220 and PCB 1240 dimensions and features, as well as the electrical interface of module 1200, as defined by the electronic circuit thereon and the electrical connectors 1244, may be standardized, with corresponding matching mechanical configuration and features implemented on PCB 1492 of assembly 1490. Electrical connectors 1244 mate with corresponding electrical connectors 1494 on PCB 1492 when Module 1200 is positioned as shown by arrow 1493 in area 1495 of PCB 1492. Exposed electrical traces on module 1200 and corresponding traces on PCB 1492 may mate in tight contact to provide electrical and/or thermal conductivity between PCB 1492 and module 1200.

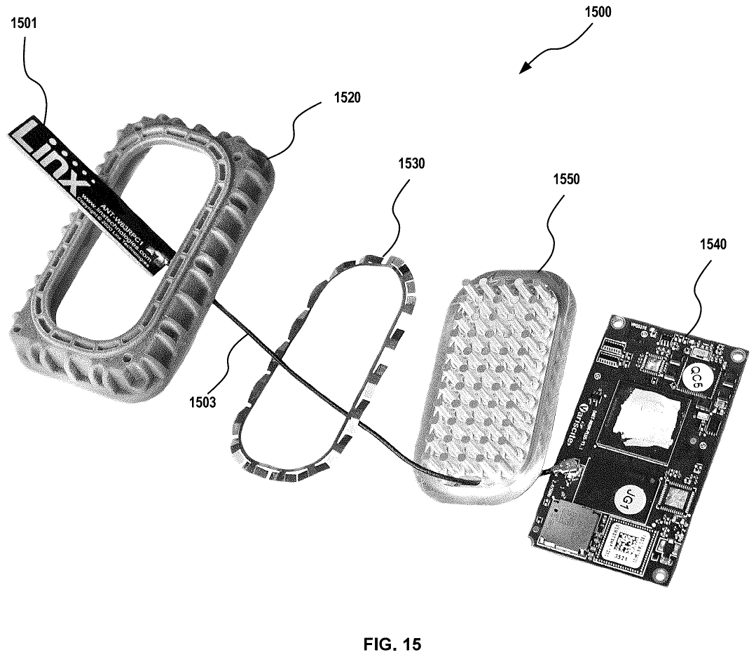

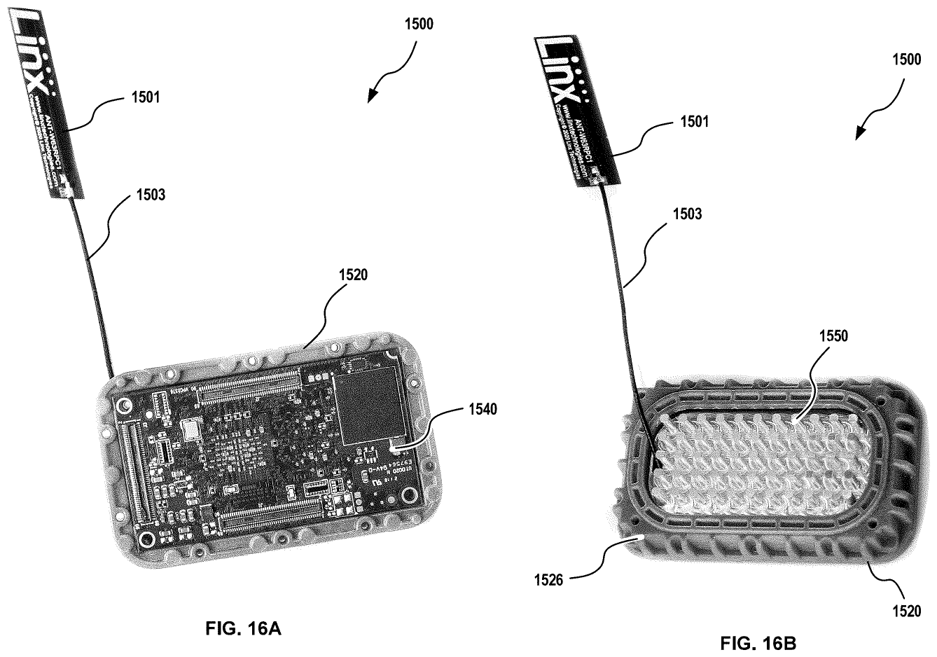

FIG. 15 illustrates details of an exploded view of another electronic module embodiment 1500 in accordance with aspects of the disclosure. Electronic module embodiment 1500 includes a housing 1520, a spring element 1530, a printed circuit board (PCB) element 1540, and a heat sink element 1550. These exemplary elements are shown for illustration purposes and should not be considered limiting; various alternate embodiments of these various elements may be used in other electronic module embodiments in accordance with aspects of the disclosure. Additional details of embodiments of these elements are described subsequently herein in conjunction with FIGS. 16A-19.

FIGS. 16A and 16B illustrate additional details of electronic module embodiment 1500 as assembled. As shown in FIGS. 15 and 16A & 16B, embodiment 1500 may include an electronic circuit board embodiment 1540, a heat sink embodiment 1550, an antenna module embodiment 1501 with an associated coaxial cable 1503, a housing or enclosure embodiment 1520, which may have an aperture to allow a heat sink to facilitate heat dissipation from inside the housing, and a spring embodiment such as spring plate embodiment 1530. These elements may be the same as or similar to other analogous elements disclosed previously herein.

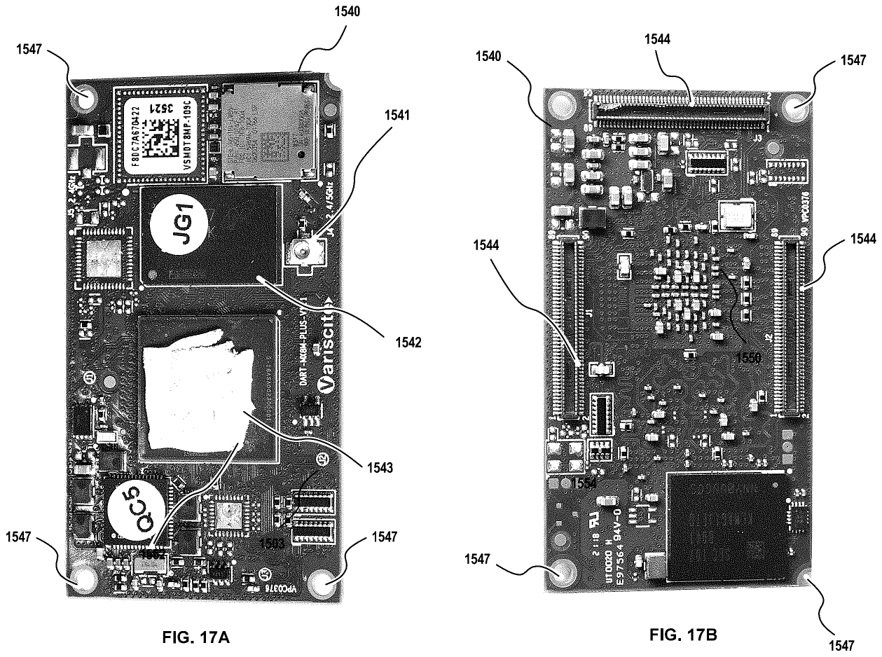

FIGS. 17A and 17B illustrate additional details of the printed circuit board (PCB) embodiment 1540 as shown in FIGS. 15 and 16A & B. FIG. 17A shows the top side of PCB 1540, which may be a system on module (“SOM”) or other electronic circuit on a circuit medium such as a PCB or other medium. FIG. 17B shows the bottom side of PCB 1540, including connectors to couple the PCB to other system components such as other PCBs or system attachment elements.

The example PCB 1540 is an electronic PCB SOM module including processing functionality, storage and/or code memory, input/output (I/O) functionality, a wireless data module for sending and/or receiving data generated on the PCB or provided to the PCB, and or other electronic circuitry. Use of PCB SOM modules such as PCB 1540 allows a user to customize the module for needs based on a particular application (e.g., as a controller for various other devices, a data collection module, or various other modular functionality which require processing, memory, I/O, wireless connectivity, and/or other functions). As such, they provide a type of generic electronics including processing, memory, I/O, radio functionality, and the like for use in other devices or systems to provide this functionality without a specially designed circuit board. Various other SoMs as well as custom designed PCBs may be used in alternate embodiments consistent with the example shown in FIGS. 15 and 16A & B.

The example SOM PCB 1540 is provided by Variscite, however, other manufacturers made similar modules. Alternately, as noted above, the PCB may be a custom designed PCB configured for a specific application or applications in other embodiments. Likewise, alternate housings, heat sinks, antennas, and spring element embodiments may be used in other electronic module embodiments consistent with the example shown in FIGS. 15 and 16A & B.

PCB 1540 includes an RF connector 1541 for connecting a coaxial cable, such as the coaxial cable 1503 coupled to antenna 1501. A radio module 1542 on PCB 1540 may provide transceiver functionality to provide data and/or analog signaling to and/or from the electronic module.

PCB 1540 can provide a highly integrated, standardized processing and mounting system on a single PCB, along with defined connections to other electronics via electrical connectors such as connectors 1544 as shown in FIG. 17B. PCB 1540 can also provide standardized holes 1547, and/or other standardized features such as described previously herein for alignment and mounting of the module to other system elements such as other PCBs or mounting elements.

In various implementations, electronic module embodiments with housings and heat sinks add the ability to SoMs to electromagnetically shield the PCB, dissipate heat from components such as processors to the environment, and/or to facilitate precise alignment of connectors, such as connectors 1544, to other circuit boards or mounting mechanisms. For example, with very fine pitch pins on connectors such as connectors 1544 as shown, a slight misalignment of the board to a corresponding mounting element (e.g., a corresponding connector or pins on another circuit board) may result in damage to the connector (e.g., as shown in FIG. 17B with the damaged connections on the left side of the connector at the upper left side of the PCB).

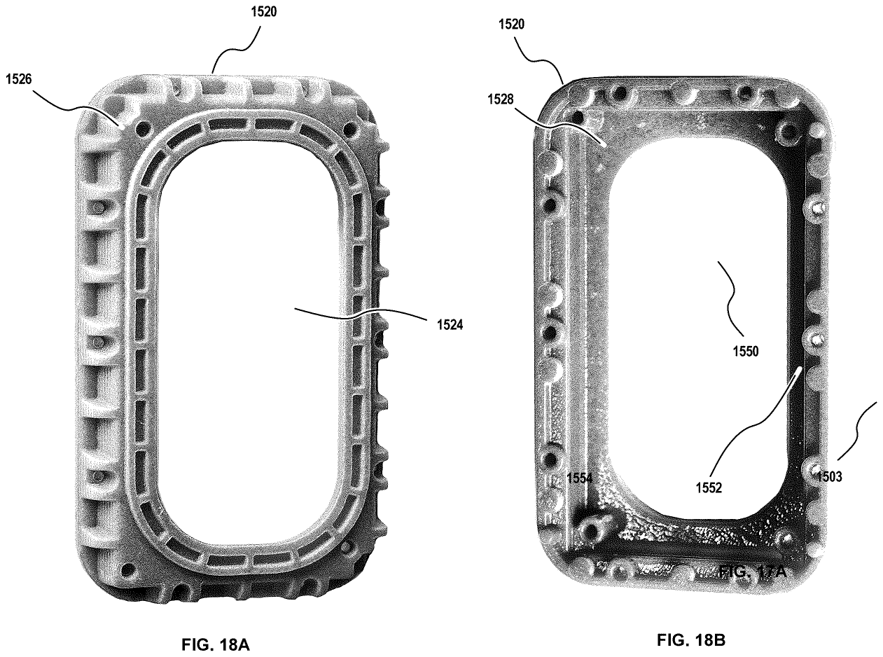

FIGS. 18A and 18B illustrate details of the embodiment 1520 of a housing or case for use in electronics module embodiments in accordance with aspects of the disclosure. Housing embodiment 1520 may comprise a plastic material in typical embodiments, however, it may also be made of metal, ceramics, or other materials, or combination thereof, in alternate embodiments.

The housing may be a plated plastic, for example, such as of a carbon fiber filled ultem (polyetherimide) or other plastic material, which may be 3D printed (such as the example shown) or may be injection molded or otherwise fabricated by techniques known or developed in the art.

The plastic may be plated with a metal such as nickel and/or copper to provide electromagnetic shielding and/or to aid in heat dissipation from heat generated by the PCB 1540. An aperture or opening 1524 may be formed in the housing 1520 to allow for penetration of a heat sink, such as heat sink 1550, from inside of the housing to the external environment to dissipate heat generated by components on the PCB. The heat sink and housing configuration is shown in, for example, FIG. 16B, with the top of the heat sink 1550 extended through the aperture. The housing and heat sink may be configured such that the combination of plated housing and heat shield, when assembled, provide a faraday-cage like shield over the enclosed PCB, while the aperture in the heat sink allows the coax (or other cabling, not shown) to connect signaling between the PCB and an external antenna or other external component or system.

As shown in FIGS. 18A & 18B, an exemplary housing embodiment such as embodiment 1520 may have an interior facing side 1528 and an exterior facing side 1526, along with an opening for positioning a heat sink, such as heat sink embodiment 1550, partially within the housing and partially external to the housing to transfer heat generated in the interior of the housing to the external atmosphere for dissipation (i.e., air or other external gases or fluids). The exterior facing side 1526 of housing 1520 is shown with the heat sink 1550 positioned in the aperture in FIG. 16B. The interior facing side of housing 1520 (not shown) is behind the PCB in FIG. 16A.

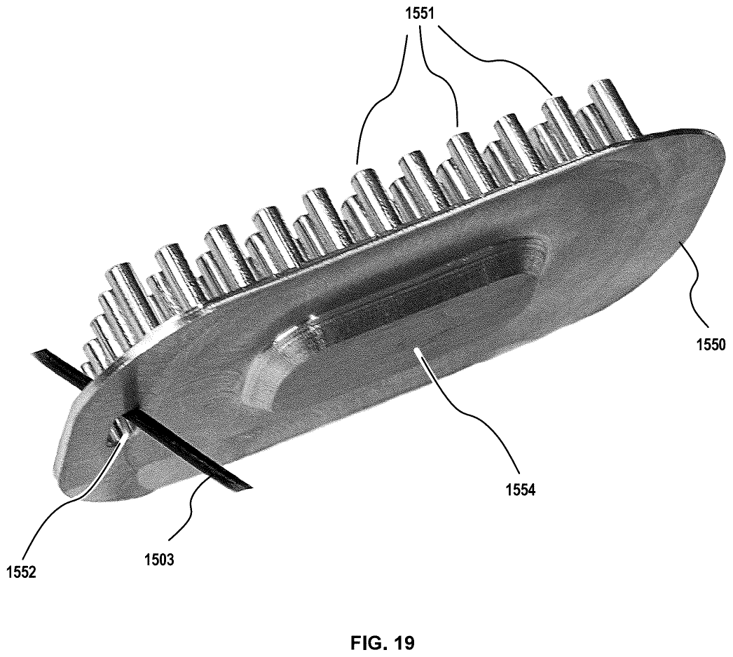

FIG. 19 illustrates details of a heat sink 1550 in an exemplary embodiment. Heat sink 1550 may comprise a metal material such as aluminum, copper, or other metallic or non-metallic heat conductive materials. Heat sink 1550 may include heat dissipation features on one or more sides such as one or more exterior facing sides. For example, in an exemplary embodiment the heat dissipation features may be a pin grid to enhance cooling, including a plurality of pins 1551 to dissipate heat to the air outside of the module's interior. The heat sink may also include a raised portion 1554 on one or more interior-facing sides to provide contact with a corresponding heat sink or integrated circuit (IC) on the PCB 1540. Other heat dissipation structures as are known or developed in the art, such as fins, arms, extended surfaces, and the like besides pin grids may also be used in various other embodiments.

[000125] A thermal interface material (TIM), such as flexible TIM material 1543 as shown in FIG. 17, may be placed between integrated circuits (ICs) on the PCB and the heat sink or a raised section 1554 of the heat sink (if the heat sink includes one) to further aid in conducting heat from the IC to the heat sink.

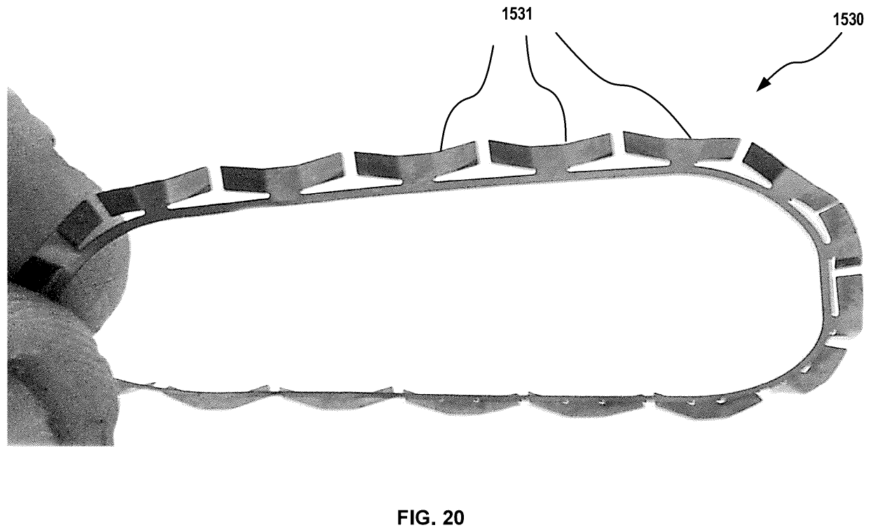

FIG. 20 illustrates details of a spring element, in the form of spring plate embodiment 1530 with a plurality of raised formed arms 1531. Such a spring plate may be used between the heat sink and housing to provide spring tension across a contact area to maintain a prescribed contact force. For example, the spring plate 1530 may be sized and shaped to maintain intimate contact between the thermal contact material 1543 (or other thermal contact areas or ICs on the PCB) and heat sink while limiting loading so that packaged PCB components such as ICs are not damaged (i.e., it acts as a mechanical buffer to maintain a desired contact force without creating excessive force at the PCB-heat sink contact area).

Screws or other mechanical connectors (now shown in FIGS. 15-20) may be used to mechanically secure the PCB and heat sink to the housing such as described previously herein in other embodiments. Screw holes and keying features may be the same as or similar to those described previously herein, for example, with respect to embodiments 100, 800, 900, 1000, 1100, 1200, and 1300. Various aspects disclosed with respect to embodiment 1500 may also be incorporated in further embodiments in conjunction with elements and features disclosed with respect to embodiments 100, 800, 900, 1000, 1100, 1200, and 1300.

As described previously herein, various embodiments in accordance with aspects of the disclosure may be used to implement various electronic circuit functionality in assemblies and devices. One example of use of modules in a utility locator assembly is shown in FIG. 9A and FIG. 9B and described previously herein. FIG. 14 illustrates another assembly embodiment, wherein a module embodiment, which may be a module such as embodiment 1200 described previously herein or another module embodiment (not shown in FIG. 14) is operatively coupled to or mounted in a circuit assembly 1490. In this example circuit assembly 1490 implements a test fixture for testing module operation, however, circuit assembly 1490 may alternate be any of various types of electronic assemblies that implement an electronic device or system or are a component of a larger electronic device or system. Other modules, such as electronic module 1500, may also be used in utility locators, utility locator transmitters, inspection camera systems, as well as in various other devices and systems.

The previous description of the disclosed embodiments is provided to enable any person skilled in the art to make or use various embodiments. Various modifications to these embodiments will be readily apparent to those skilled in the art, and the generic principles defined herein may be applied to other embodiments without departing from the spirit or scope of the disclosure.

Accordingly, the presently claimed invention is not intended to be limited to the aspects shown herein, but is to be accorded the full scope consistent with the specification and drawings, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a, b, c; a and b; a and c; b and c; and a, b and c.

The previous description of the disclosed aspects is provided to enable any person skilled in the art to make or use embodiment of the present disclosure. Various modifications to these aspects will be readily apparent to those skilled in the art, and the generic principles defined herein may be applied to other aspects without departing from the spirit or scope of the disclosure. Thus, the scope of the present disclosure is not intended to be limited to only the specific aspects shown herein but should be accorded the widest scope consistent with the embodiments herein and their equivalents.

1. An electronic circuit module, comprising:
an injection molded housing or case with at least a partially electrically conductive surface, the injection molded housing or case including one or more alignment holes and one or more alignment pins;
an electronic circuit board disposed in the housing or case, the electronic circuit board including:
one or more electrically conductive surfaces on one or both sides to provide electrical connections to the at least partially electrically conductive surface of the housing or case; and
electronic components disposed on one or both sides of the electronic circuit board;
a plurality of screws for securing the electronic circuit board to the housing or case and providing an electrical connection between the housing and the electronic circuit board electrically conductive surfaces; and
a high density electrical connector to couple a corresponding electrical cable to provide electrical connections between the electronic circuit board and another circuit board or other electrical connection point.

2. The module of claim 1, wherein the housing or case comprises a thermoplastic material.

3. The module of claim 2, wherein the thermoplastic material is electrically conductive.

4. The module of claim 3, wherein the thermoplastic material is a conductive fiber or flake reinforced.

5. The module of claim 3, wherein the housing or case comprises carbon fiber.

6. The module of claim 3, wherein the housing or case is about 40 percent filled with a PEI, Ultem plastic.

7. The module of claim 1, wherein the housing or case is plated with a conductive material to form the at least partially conductive surface.

8. The module of claim 7, wherein the conductive material comprises copper.

9. the module of claim 8, wherein the housing is further plated with nickel over at least a portion of the copper.

10. The module of claim 1, wherein the screws are self-threading screws.

11. The module of claim 10, further comprising a second plurality of screws to secure the housing or case to the another circuit board or a base or another mounting surface.

12. The module of claim 11, wherein the other mounting surface is a metallic case or frame.

13. The module of claim 11, further including the corresponding cable between the electronic circuit board and the other electrical connection point.

14. The module of claim 1, wherein the electrical connector has a contact pitch of about one millimeter or less.

15. The module of claim 14, wherein the connector has a mated height of between about 0.5 mm and 6 mm.

16. The module of claim 1, wherein the housing or case is at least partially plated with a conductive material and the housing or case includes one or more tap holes in the at least partially plated area.

17. The module of claim 7, wherein part of the injection molded housing or case partially conductive surface is in close physical contact with part of the one or more conductive surface on the electronic circuit to form an electrically conductive path therebetween.

18. The module of claim 17, wherein part of the injection molded housing or case partially conductive surface is in close physical contact with a conductive area of the another circuit board or other electrical connection area.

19. The module of claim 18, wherein the other electrical connection area comprises another mounting surface and the another mounting surface is at least partially conductive to form an electrically conductive path between the injection molded housing or case and the another mounting surface.

20. The module of claim 1, wherein the one or more alignment holes and one or more alignment pins are plated with an electrically conductive material.

21-59. (canceled)
